(19) United States
(12) Patent Application Publication
(10) Pub. No.: US 2024/0292620 A1
(43) Pub. Date: Aug. 29, 2024

(54) SEMICONDUCTOR MEMORY DEVICE AND MANUFACTURING METHOD OF SEMICONDUCTOR MEMORY DEVICE

(71) Applicant: Kioxia Corporation, Tokyo (JP)

(72) Inventor: Takahiro KOTOU, Yokkaichi Mie (JP)

(73) Assignee: Kioxia Corporation, Tokyo (JP)

(21) Appl. No.: 18/586,787

(22) Filed: Feb. 26, 2024

(30) Foreign Application Priority Data
Feb. 27, 2023 (JP) 2023-028090

(51) Int. Cl. H10B 43/27

(52) U.S. Cl. CPC H10B 43/27

(57) ABSTRACT

A semiconductor memory device is provided with a stacked body in which a plurality of conductive layers and a plurality of insulating layers are alternately stacked by one layer, a first separation layer that penetrates an uppermost conductive layer of the stacked body and at least one conductive layer continuous with the uppermost conductive layer in the stacking direction among the plurality of conductive layers, extends in the stacked body in a first direction intersecting the stacking direction, and selectively separates one or more conductive layers including the uppermost conductive layer in a second direction that intersects with the stacking direction and the first direction, a first contact that extends from an upper side of the stacked body and is connected to any one of the one or more conductive layers, and a second contact that extends from the upper side of the stacked body, is connected to any one of the plurality of conductive layers lower than the one or more conductive layers, and has a diameter, which is larger than that of an upper surface of the first contact, on an upper surface.

### CROSS-REFERENCE TO RELATED APPLICATION

This application is based upon and claims the benefit of priority from Japanese Patent Application No. 2023-028090, filed Feb. 27, 2023, the entire contents of which are incorporated herein by reference.

### FIELD

Embodiments described herein relate generally to a semiconductor memory device and a manufacturing method of a semiconductor memory device.

### BACKGROUND

In a semiconductor memory device such as a three-dimensional non-volatile memory, memory cells are formed in three dimensions in a stacked body in which a plurality of conductive layers are stacked. In order to draw out these conductive layers, a plurality of contacts extending in the stacked body and connected to any of the plurality of conductive layers are disposed. As the number of conductive layers stacked increases, there is a concern that the arrangement region of the contacts increases and the semiconductor memory device becomes larger.

### DESCRIPTION OF THE DRAWINGS

FIG. 1 is a cross-sectional view showing a schematic configuration example of a semiconductor memory device according to Embodiment 1.

FIGS. 2A to 2C are diagrams showing an example of a configuration of the semiconductor memory device according to Embodiment 1.

FIGS. 3A and 3B are diagrams showing an example of the configuration of the semiconductor memory device according to Embodiment 1.

FIGS. 4A to 4C are diagrams sequentially illustrating some procedures of the manufacturing method of the semiconductor memory device according to Embodiment 1.

FIGS. 5A and 5B are diagrams sequentially illustrating some procedures of the manufacturing method of the semiconductor memory device according to Embodiment 1.

FIGS. 6A and 6B are diagrams sequentially illustrating some procedures of the manufacturing method of the semiconductor memory device according to Embodiment 1.

FIGS. 7A and 7B are diagrams sequentially illustrating some procedures of the manufacturing method of the semiconductor memory device according to Embodiment 1.

FIGS. 8A to 8C are diagrams sequentially illustrating some procedures of the manufacturing method of the semiconductor memory device according to Embodiment 1.

FIGS. 9A to 9C are diagrams sequentially illustrating some procedures of the manufacturing method of the semiconductor memory device according to Embodiment 1.

FIGS. 10A to 10C are diagrams sequentially illustrating some procedures of the manufacturing method of the semiconductor memory device according to Embodiment 1.

FIGS. 11A and 11B are diagrams sequentially illustrating some procedures of the manufacturing method of the semiconductor memory device according to Embodiment 1.

FIGS. 12A and 12B are diagrams sequentially illustrating some procedures of the manufacturing method of the semiconductor memory device according to Embodiment 1.

FIGS. 13A and 13B are diagrams sequentially illustrating some procedures of the manufacturing method of the semiconductor memory device according to Embodiment 1.

FIGS. 14A and 14B are diagrams sequentially illustrating some procedures of the manufacturing method of the semiconductor memory device according to Embodiment 1.

FIGS. 15A and 15B are diagrams sequentially illustrating some procedures of the manufacturing method of the semiconductor memory device according to Embodiment 1.

FIGS. 16A and 16B are diagrams sequentially illustrating some procedures of the manufacturing method of the semiconductor memory device according to Embodiment 1.

FIGS. 17A and 17B are diagrams sequentially illustrating some procedures of the manufacturing method of the semiconductor memory device according to Embodiment 1.

FIGS. 18A and 18B are diagrams sequentially illustrating some procedures of the manufacturing method of the semiconductor memory device according to Embodiment 1.

FIGS. 19A and 19B are diagrams sequentially illustrating some procedures of the manufacturing method of the semiconductor memory device according to Embodiment 1.

FIGS. 20A and 20B are diagrams sequentially illustrating some procedures of the manufacturing method of the semiconductor memory device according to Embodiment 1.

FIGS. 21A and 21B are diagrams showing an example of a configuration of a semiconductor memory device according to Modification Example 1 of Embodiment 1.

FIGS. 22A and 22B are diagrams sequentially illustrating some procedures of the manufacturing method of the semiconductor memory device according to Modification Example 1 of Embodiment 1.

FIGS. 23A and 23B are diagrams sequentially illustrating some procedures of the manufacturing method of the semiconductor memory device according to Modification Example 1 of Embodiment 1.

FIGS. 24A and 24B are diagrams sequentially illustrating some procedures of the manufacturing method of the semiconductor memory device according to Modification Example 1 of Embodiment 1.

FIGS. 25A and 25B are diagrams sequentially illustrating some procedures of the manufacturing method of the semiconductor memory device according to Modification Example 1 of Embodiment 1.

FIGS. 26A and 26B are diagrams sequentially illustrating some procedures of the manufacturing method of the semiconductor memory device according to Modification Example 1 of Embodiment 1.

FIGS. 27A to 27C are cross-sectional views showing a state in which a contact is formed in the semiconductor memory device according to Modification Example 1 and a comparative example of Embodiment 1.

FIGS. 28A and 28B are diagrams showing an example of a configuration of a semiconductor memory device according to Modification Example 2 of Embodiment 1.

FIGS. 29A to 29D are diagrams sequentially illustrating some procedures of the manufacturing method of the semiconductor memory device according to Modification Example 2 of Embodiment 1.

FIGS. 30A to 30D are diagrams sequentially illustrating some procedures of the manufacturing method of the semiconductor memory device according to Modification Example 2 of Embodiment 1.

FIGS. 31A and 31B are diagrams showing an example of a configuration of the semiconductor memory device according to Embodiment 2.

FIGS. 32A and 32B are diagrams sequentially illustrating some procedures of the manufacturing method of the semiconductor memory device according to Embodiment 2.

FIGS. 33A and 33B are diagrams sequentially illustrating some procedures of the manufacturing method of the semiconductor memory device according to Embodiment 2.

FIGS. 34A and 34B are diagrams sequentially illustrating some procedures of the manufacturing method of the semiconductor memory device according to Embodiment 2.

FIGS. 35A and 35B are diagrams sequentially illustrating some procedures of the manufacturing method of the semiconductor memory device according to Embodiment 2.

FIGS. 36A and 36B are diagrams sequentially illustrating some procedures of the manufacturing method of the semiconductor memory device according to Embodiment 2.

FIGS. 37A and 37B are diagrams sequentially illustrating some procedures of the manufacturing method of the semiconductor memory device according to Embodiment 2.

FIGS. 38A and 38B are diagrams showing an example of a configuration of a semiconductor memory device according to a modification example of Embodiment 2.

### DETAILED DESCRIPTION

Embodiments provide a semiconductor memory device and a manufacturing method of a semiconductor memory device, which can reduce an arrangement region of contacts.

In general, according to at least one embodiment, a semiconductor memory device is provided with a stacked body in which a plurality of conductive layers and a plurality of insulating layers are alternately stacked by one layer, a pillar that extends in the stacked body in a stacking direction of the stacked body and forms a memory cell in each of intersection portions with some of the plurality of conductive layers, a first separation layer that penetrates an uppermost conductive layer of the stacked body and at least one conductive layer continuous with the uppermost conductive layer in the stacking direction among the plurality of conductive layers, extends in the stacked body in a first direction intersecting the stacking direction, and selectively separates one or more conductive layers including the uppermost conductive layer in a second direction that intersects with the stacking direction and the first direction, a first contact that extends from an upper side of the stacked body and is connected to any one of the one or more conductive layers, and a second contact that extends from the upper side of the stacked body, is connected to any one of the plurality of conductive layers lower than the one or more conductive layers, and has a diameter, which is larger than that of an upper surface of the first contact, on an upper surface.

Hereinafter, embodiments of the present disclosure will be described in detail with reference to the drawings. Further, the present disclosure is not limited to the following embodiment. The elements in the following embodiments include those that can be easily assumed by those skilled in the art or those that are substantially the same.

### Embodiment 1

Hereinafter, Embodiment 1 will be described in detail with reference to the drawings.

### Configuration Example of Semiconductor Memory Device

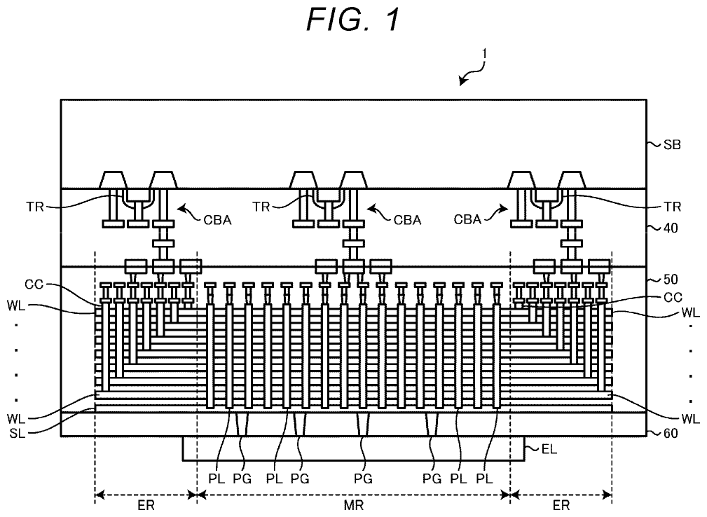

FIG. 1 is a cross-sectional view showing a configuration example of a semiconductor memory device 1 according to Embodiment 1. Meanwhile, in FIG. 1, hatching is omitted in consideration of the visibility of the drawing.

As shown in FIG. 1, the semiconductor memory device 1 is provided with an electrode film EL, a source line SL, and a plurality of word lines WL in order from a lower side of the plane of the drawing. In addition, the semiconductor memory device 1 is provided with a peripheral circuit CBA provided on the semiconductor substrate SB above the plurality of word lines WL.

The source line SL is disposed on the electrode film EL via an insulating layer 60. A plurality of plugs PG are disposed in the insulating layer 60, and the source line SL and the electrode film EL are electrically conducted via the plugs PG. Accordingly, source potential can be applied to the source line SL from an outside of the semiconductor memory device 1 via the electrode film EL and the plug PG.

A plurality of word lines WL are stacked on the source line SL. A memory region MR is disposed in a central portion of the plurality of word lines WL, and contact regions ER are disposed in both end portions of the plurality of word lines WL.

A plurality of pillars PL penetrating the word line WL in a stacking direction are disposed in the memory region MR. A plurality of memory cells are formed in an intersection portion between the pillar PL and the word line WL. Accordingly, the semiconductor memory device 1 is configured as, for example, a three-dimensional non-volatile memory in which memory cells are disposed in three dimensions in the memory region MR.

A plurality of contacts CC connected to each of the plurality of word lines WL are disposed in the contact region ER. In the present specification, in an extension direction of the contact CC, an end side of the contact CC connected with the word line WL is referred to as a lower side of the semiconductor memory device 1.

From the contact CC, a write voltage, a read voltage, and the like are applied to the memory cells disposed in the memory region MR of the central portion of the plurality of word lines WL via the word line WL having the same height position as the memory cells. As described above, the word lines WL that are stacked in multiple layers are individually drawn out by these contacts CC.

The plurality of word lines WL, pillars PL, and contacts CC are covered with the insulating layer 50. The insulating layer 50 also extends around the plurality of word lines WL.

The semiconductor substrate SB above the insulating layer 50 is, for example, a silicon substrate or the like. The peripheral circuit CBA provided with a transistor TR, a wiring, and the like is disposed on a surface of the semiconductor substrate SB. Various voltages applied from the contact CC to the memory cell are controlled by the peripheral circuit CBA electrically connected to the contact CC. In this way, the peripheral circuit CBA controls an electrical operation of the memory cell.

The peripheral circuit CBA is covered with the insulating layer 40, and the insulating layer 40 and the insulating layer 50 covering the plurality of word lines WL are bonded to each other, whereby the semiconductor memory device 1 provided with a configuration of the plurality of word lines WL, pillars PL, contacts CC, and the like and the peripheral circuit CBA are configured.

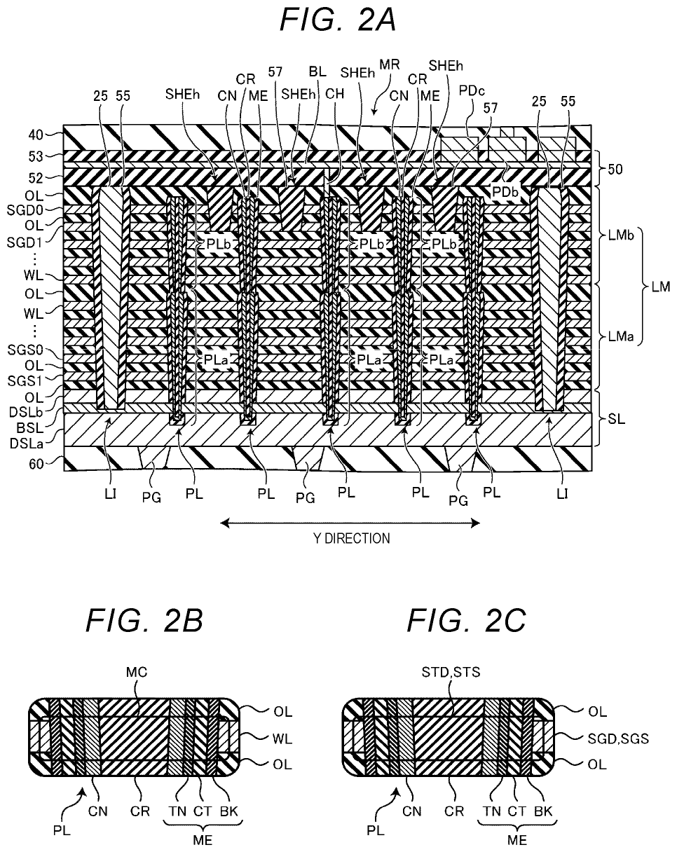

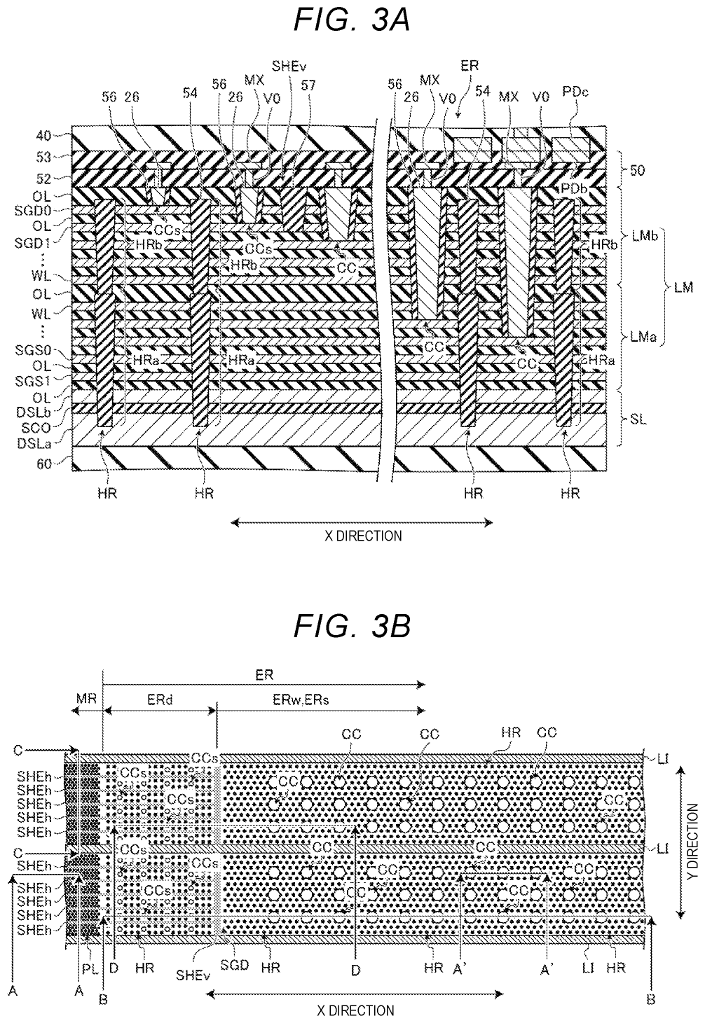

Next, a detailed configuration example of the semiconductor memory device 1 will be described with reference to FIGS. 2A to 2C and FIGS. 3A and 3B. FIGS. 2A to 2C and FIGS. 3A and 3B are diagrams showing an example of a configuration of the semiconductor memory device 1 according to Embodiment 1.

More specifically, FIG. 2A is a cross-sectional view taken along a Y direction showing an example of a configuration of the memory region MR. FIG. 2B is an enlarged sectional view at a height position of the word line WL of the pillar PL disposed in the memory region MR. FIG. 2C is an enlarged sectional view at a height position of select gate lines SGD and SGS of the pillar PL disposed in the memory region MR.

FIG. 3A is a cross-sectional view taken along an X direction showing an example of a configuration of the contact region ER. FIG. 3B is an XY cross-sectional view including the contact region ER at the height position of the select gate line SGD.

Meanwhile, in FIGS. 2A and 3A, the structure below the insulating layer 60 and the structure above the insulating layer 40 are not shown. In addition, each of FIGS. 2A to 2C and FIGS. 3A and 3B schematically shows the configuration of the semiconductor memory device 1. Therefore, the number, the arrangement, and the like of each configuration in the cross-sectional views in the X direction or the Y direction of FIGS. 2A and 3A and those in the XY cross-sectional view of FIG. 3B do not necessarily match.

An A-A line to a D-D line shown in FIG. 3B are cross sections in each view showing a manufacturing method of the semiconductor memory device 1 to be described later. Meanwhile, the number, the arrangement, and the like of each configuration in the cross-sectional view showing the manufacturing method of the semiconductor memory device 1 and those in the XY cross-sectional view of FIG. 3B may not necessarily match.

In addition, in the present specification, both the X direction and the Y direction are directions along the orientation of the plane of the word line WL, and the X direction and the Y direction are orthogonal to each other. In addition, an electrical drawing direction of the word line WL may be referred to as a first direction, and the first direction is a direction along the X direction. In addition, a direction intersecting the first direction may be referred to as a second direction, and the second direction is a direction along the Y direction. However, since there may be a manufacturing error in the semiconductor memory device 1, the first direction and the second direction are not necessarily orthogonal to each other.

As shown in FIG. 2A, the source line SL has a multilayer structure in which, for example, a lower source line DSLa, an intermediate source line BSL, and an upper source line DSLb are stacked in this order on the insulating layer 60.

The lower source line DSLa, the intermediate source line BSL, and the upper source line DSLb are, for example, a polysilicon layer or the like. Among the above, at least the intermediate source line BSL may be a conductive polysilicon layer or the like in which impurities are diffused.

A stacked body LM is disposed on the source line SL. The stacked body LM is provided with stacked bodies LMa and LMb in which the plurality of word lines WL and a plurality of insulating layers OL are alternately stacked by one layer. The stacked body LMa is disposed above the source line SL, and the stacked body LMb is disposed on the stacked body LMa.

One or more select gate lines SGS are disposed via the insulating layer OL in a further lower layer of the word line WL of the lowermost layer of the stacked body LM. In the example of FIG. 2A, the stacked body LMa is provided with two select gate lines SGS0 and SGS1 in order from an upper layer side. One or more select gate lines SGD are disposed on an upper layer of the uppermost word line WL of the stacked body LMb via the insulating layer OL. In the example of FIG. 2A, the stacked body LMb is provided with two select gate lines SGD0 and SGD1 in order from an upper layer side.

Meanwhile, the number of layers of the word lines WL and the select gate lines SGD and SGS in the stacked body LM is optional.

The word lines WL and the select gate lines SGD and SGS as the plurality of conductive layers are, for example, a tungsten layer, a molybdenum layer, or the like. The plurality of insulating layers OL are, for example, a silicon oxide layer or the like.

The uppermost insulating layers OL of the stacked bodies LMa and LMb are respectively thicker than, for example, the other insulating layers OL in the stacked bodies LMa and LMb. The uppermost insulating layer OL of the stacked body LMa is in contact with the word line WL of the lowermost layer of the stacked body LMb, and insulating layers 52 and 53 are disposed in this order on the uppermost insulating layer OL of the stacked body LMb. The insulating layers 52 and 53 form a part of the insulating layer 50 described above, and an upper surface of the insulating layer 53 is in contact with a lower surface of the insulating layer 40 on a peripheral circuit CBA side.

As shown in FIG. 2A and FIG. 3B, the stacked body LM is separated in the Y direction by a plurality of plate-shaped contacts LI.

That is, each of the plate-shaped contacts LI is arranged in the Y direction, and extends in a direction along the stacking direction and the X direction of the stacked body LM. As described above, the plate-shaped contact LI continuously extends in the stacked body LM from one end portion to the other end portion of the stacked body LM in the X direction. In addition, the plate-shaped contact LI penetrates the stacked body LM and the upper source line DSLb and reaches the intermediate source line BSL.

In addition, each of the plate-shaped contacts LI is provided with an insulating layer 55 and a conductive layer 25. The insulating layer 55 is, for example, a silicon oxide layer or the like. The conductive layer 25 is, for example, a tungsten layer or a conductive polysilicon layer.

The insulating layer 55 covers a side wall of the plate-shaped contact LI facing the Y direction. The insulating layer 55 is filled with the conductive layer 25 and the conductive layer 25 is electrically connected to the source line SL provided with the intermediate source line BSL. In addition, the conductive layer 25 is connected to an upper-layer wiring in a cross section different from that in FIG. 2A. With such a configuration, the plate-shaped contact LI functions as a source line contact.

Meanwhile, instead of the plate-shaped contact LI, a plate-shaped member filled with an insulating layer may penetrate the stacked body LM and extend in the direction along the X direction, so that the stacked body LM may be separated in the Y direction. In this case, such a plate-shaped member does not have a function as a source line contact.

As shown in FIG. 2A and FIG. 3B, separation layers SHEh as a plurality of first separation layers are disposed between the plate-shaped contacts LI adjacent to each other in the Y direction. The separation layer SHEh is an insulating layer 57, such as a silicon oxide layer, that penetrates the select gate lines SGD0 and SGD1 of the stacked body LMb and reaches the insulating layer OL immediately below the select gate line SGD1, and extends in the direction along the X direction in the memory region MR of the stacked body LM. With such a configuration, the separation layer SHEh selectively separates the select gate lines SGD0 and SGD1 between the plate-shaped contacts LI in the Y direction.

The plurality of pillars PL, which penetrates the stacked body LM, the upper source line DSLb, and the intermediate source line BSL and reaches the lower source line DSLa, are disposed in the memory region MR of the stacked body LM.

The plurality of pillars PL are disposed, for example, in a zigzag shape when viewed in the stacking direction of the stacked body LM. Each of the pillars PL has a shape such as a circular shape, an elliptical shape, or an oblong shape (oval shape) as a cross-sectional shape in a direction along a layer direction of the stacked body LM, that is, the direction along the XY plane.

The pillar PL is provided with a pillar PLa that penetrates the stacked body LMa from the uppermost insulating layer OL of the stacked body LMa to reach the source line SL and a pillar PLb that penetrates the stacked body LMb from the uppermost insulating layer OL of the stacked body LMb to reach the uppermost insulating layer OL of the stacked body LMa and is connected to an upper end portion of the corresponding pillar PLa.

Each of the plurality of pillars PL has a memory layer ME extending in the stacked body LM in the stacking direction, a channel layer CN penetrating the stacked body LM and connected to the intermediate source line BSL, and a core layer CR serving as a core of the pillar PL.

The memory layer ME is disposed on a side surface of the pillar PL excluding a depth position of the intermediate source line BSL. In addition, the memory layer ME is also disposed on a lower surface of the pillar PL reaching a depth of the lower source line DSLa.

The channel layer CN penetrates the stacked body LM, the upper source line DSLb, and the intermediate source line BSL inside the memory layer ME, and reaches the depth of the lower source line DSLa. That is, the channel layer CN is disposed on the side surface and the lower surface of the pillar PL via the memory layer ME. A further inside of the channel layer CN is filled with the core layer CR.

Meanwhile, a part of the channel layer CN is in contact with the intermediate source line BSL on a side surface, and thus is electrically connected to the source line SL provided with the intermediate source line BSL. In addition, an upper end portion of the channel layer CN is connected to the bit line BL extending in the direction along the Y direction in the insulating layer 53 via a plug CH disposed in the insulating layer 52.

As shown in FIGS. 2B and 2C, the memory layer ME has a multilayer structure in which a block insulating layer BK, a charge storage layer CT, and a tunnel insulating layer TN are stacked in this order from an outer peripheral side of the pillar PL.

The block insulating layer BK and the tunnel insulating layer TN of the memory layer ME and the core layer CR are, for example, a silicon oxide layer or the like. The charge storage layer CT of the memory layer ME is, for example, a silicon nitride layer or the like. The channel layer CN is, for example, a semiconductor layer such as a polysilicon layer or an amorphous silicon layer.

As shown in FIG. 2B, according to the above configuration, a memory cell MC is formed in each of the portions of the side surface of the pillar PL facing the individual word lines WL. A predetermined voltage is applied from the word line WL to write and read data to and from the memory cell MC.

The data from the memory cell MC is read and transmitted to the bit line BL connected to the pillar PL. The bit line BL is connected to the electrode pad PDb disposed on the surface of the insulating layer 53. The electrode pad PDb is disposed on the surface of the insulating layer 40 and is connected to the electrode pad PDc that is electrically connected to the peripheral circuit CBA. Accordingly, the data of the memory cell MC read and transmitted to the bit line BL is processed by the peripheral circuit CBA.

As shown in FIG. 2C, with the above configuration, the select gate STD is formed in each of the portions of the side surface of the pillar PL facing the individual select gate lines SGD. In addition, a select gate STS is formed in each of portions of the side surface of the pillar PL facing the individual select gate lines SGS. A predetermined voltage is applied to the select gate lines SGD and SGS to turn on or off the select gates STD and STS, and the memory cell MC formed in the pillar PL to which the select gates STD and STS belong is in a selected state or a non-selected state.

As shown in FIG. 3A, in the contact region ER, the source line SL has an intermediate insulating layer SCO between the lower source line DSLa and the upper source line DSLb instead of the intermediate source line BSL. This is because the pillar PL to be connected to the source line SL is not disposed in the contact region ER. The intermediate insulating layer SCO is, for example, a silicon oxide layer or the like. Meanwhile, the source line SL may have the intermediate source line BSL also in the contact region ER.

In addition, in the contact region ER, a plurality of contacts CCs, CC and a plurality of columnar portions HR are disposed.

The plurality of contacts CCs as first contacts extend in the stacked body LMb in the stacking direction of the stacked body LM, each of which is connected to any one of the one or more select gate lines SGD provided in the stacked body LMb.

The plurality of contacts CC as second contacts extend in the stacked bodies LMa and LMb in the stacking direction of the stacked body LM, each of which is connected to any of the plurality of word lines WL belonging to the stacked body LMa.

In addition, although not shown in the drawing, the contacts are also connected to the one or more select gate lines SGS provided in the stacked body LMa, respectively. Hereinafter, unless otherwise specified, the contact CC connected to the word line WL is provided with these contacts connected to the select gate line SGS.

The upper end portions of the contacts CCs and CC are disposed in, for example, the uppermost insulating layer OL of the stacked body LMb. In addition, the lower end portions of the contacts CCs and CC reach the word line WL or the select gate lines SGD and SGS to be connected.

In addition, an area and a diameter of the upper surface of the contact CCs connected to the select gate line SGD are smaller than an area and a diameter of the upper surface of the contact CC connected to the word line WL and the like. Furthermore, since the contact CCs generally have a size smaller than that of the contact CC, an area and a diameter of a cross section of the contact CCs along the XY plane may be smaller than an area and a diameter of a cross section of the contact CC connected to the word line WL or the like along the XY plane at the same height position as the stacked body LM.

As shown in FIG. 3B, a region of the contact region ER in which a plurality of contacts CCs are disposed is referred to as a contact region ERd. In addition, a region in which a plurality of contacts CC connected to the word line WL are disposed is referred to as a contact region ERw. In addition, a region in which a plurality of contacts connected to the select gate line SGS are disposed is referred to as a contact region ERs.

In the region sandwiched between the plate-shaped contacts LI, a separation layer SHEv as a second separation layer extending in the direction along the Y direction in the stacked body LM is disposed between the contact regions ERd and ERw. The separation layer SHEv is the insulating layer 57 such as a silicon oxide layer, as in the above-described separation layer SHEh, and penetrates the select gate lines SGD0 and SGD1 and reaches the insulating layer OL immediately below.

In addition, the plurality of separation layers SHEh extend in the direction along the X direction in the memory region MR between the plate-shaped contacts LI, and also extend in the direction along the X direction in the contact region ERd in which the plurality of contacts CCs connected to the select gate line SGD are disposed, and are connected to the side surface of the separation layer SHEv.

Accordingly, both end portions of the select gate line SGD in the Y direction are sandwiched by the plate-shaped contact LI and the separation layer SHEh, or by two separation layer SHEh, and the end portion of the select gate line SGD in the X direction is selectively separated into a plurality of regions separated by the separation layer SHEv.

FIG. 3B shows an example in which the stacked body LM is provided with four select gate lines SGD and these select gate lines SGD are separated into six regions. Therefore, in the example of FIG. 3B, the select gate line SGD is separated into six regions by the five separation layers SHEh, the plate-shaped contacts L and I on both sides thereof in the Y direction, and the one separation layer SHEv, and the contacts CCs connected to each of the four layers of the select gate lines SGD are arranged in the X direction in the plurality of regions.

As shown in FIG. 3A, the contacts CCs and CC have an insulating layer 56 that covers an outer periphery of the contact CC and a conductive layer 26 such as a tungsten layer or a copper layer with which an inside of the insulating layer 56 is filled.

The conductive layers 26 of the contacts CCs and CC are connected to the upper-layer wiring MX disposed in the insulating layer 53 via a plug V0 disposed in the insulating layer 52. The upper-layer wiring MX is electrically connected to the peripheral circuit CBA (refer to FIG. 1) described above via the electrode pad PDb on the surface of the insulating layer 53 and the electrode pad PDc on the surface of the insulating layer 40.

With such a configuration, the word lines WL and the select gate lines SGD and SGS of each layer can be electrically drawn out.

That is, with the above configuration, the predetermined voltage can be applied to the memory cell MC from the peripheral circuit CBA via the upper-layer wiring MX, the contact CC, and the word line WL, so that the memory cell MC can be operated as a storage element.

In addition, a predetermined voltage is applied to the select gate lines STD, STS from the peripheral circuit CBA via the upper-layer wiring MX, the contact CCs, and the select gate lines SGD and SGS, so that the memory cell MC can be set to a selected state or a non-selected state. At this time, the memory cell MC enters a selected state or a non-selected state for each region separated by the separation layers SHEh and SHEv.

In the contact region ER in which the plurality of contacts CCs and CC are disposed, the plurality of columnar portions HR that penetrate the stacked body LM, the upper source line DSLb and the intermediate insulating layer SCO, and reaches the lower source line DSLa are disposed in a dispersed manner. The plurality of columnar portions HR are disposed, for example, in a grid shape or a zigzag shape when viewed in the stacking direction of the stacked body LM. Each of the columnar portions HR has a shape such as a circular shape, an elliptical shape, or an oblong shape as a cross-sectional shape in the direction along the XY plane.

In the example of FIG. 3A, the plurality of columnar portions HR are disposed between the plurality of contacts CCs and CC. However, the plurality of columnar portions HR are disposed at a pitch smaller than at least the diameter of the individual contacts CC, and the interference between the plate-shaped contacts LI and the contacts CCs and CC is allowed. That is, some of the plurality of columnar portions HR may be disposed at a position in which at least a part overlaps the adjacent contacts CC, for example. In this case, a portion overlapping the contact CC may be eroded by the contact CC, and a part of the columnar portion HR may be in a state of being damaged.

In addition, each of the columnar portions HR is provided with a columnar portion HRa that penetrates the stacked body LMa from the uppermost insulating layer OL of the stacked body LMa to reach the source line SL, and a columnar portion HRb that penetrates the stacked body LMb from the uppermost insulating layer OL of the stacked body LMb to reach the uppermost insulating layer OL of the stacked body LMa and is connected to an upper end portion of the corresponding columnar portion HRa.

As will be described later, the columnar portions HR have a role of supporting these configurations when forming the stacked body LM from the stacked body in which the sacrificial layer and the insulating layer are stacked, and are dummy pillars that do not contribute to the function of the semiconductor memory device 1.

Therefore, each of the columnar portions HRa and HRb is formed of only the insulating layer 54 such as the silicon oxide layer, and the columnar portion HR is configured not to have an electrical influence on other configurations. Accordingly, in the plurality of columnar portions HR, interference with the adjacent plate-shaped contacts LI and contacts CCs and CC is allowed. By configuring the columnar portion HR in this way, the columnar portion HR can be disposed at a desired pitch without avoiding contact with the plate-shaped contact LI and the contacts CCs and CC.

In addition, at the same height position as the stacked body LM, the cross-sectional area of the columnar portion HR in the direction along the XY plane may be larger than, for example, the cross-sectional area of the pillar PL in the direction along the XY plane. In addition, the pitch between the plurality of columnar portions HR may be larger than the pitch between the plurality of pillars PL, for example. In the XY plane, the arrangement density of the columnar portion HR per unit area of the word line WL in the stacked body LM may be lower than the arrangement density of the pillar PL per unit area of the word line WL.

In this way, for example, by configuring the cross-sectional area of the pillar PL to be smaller than that of the columnar portion HR and forming the pillar PL to have a narrow pitch, a large number of memory cells MC can be formed at a high density in the stacked body LM having a predetermined size, and the storage capacity of the semiconductor memory device 1 can be increased. Meanwhile, since the columnar portion HR is used exclusively to support the stacked body LM, for example, the manufacturing load of the semiconductor memory device 1 can be reduced by not forming the columnar portion HR to have a precise configuration in which the cross-sectional area is small and a pitch is small like the pillar PL.

### Manufacturing Method of Semiconductor Memory Device

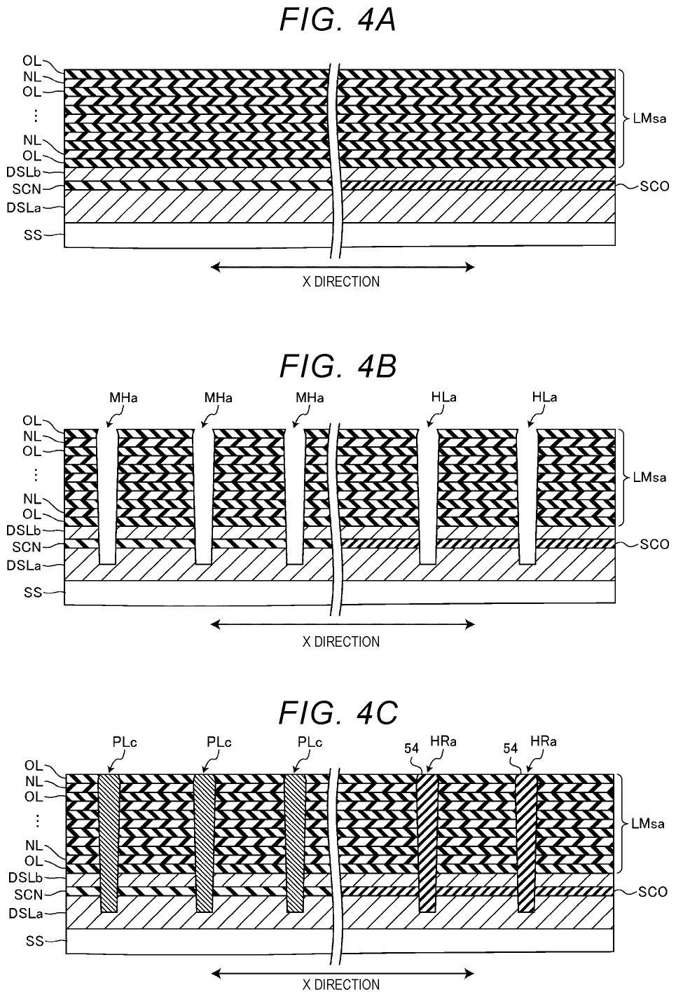

Next, a manufacturing method of a semiconductor memory device according to Embodiment 1 will be described with reference to FIGS. 4A to 19B. FIGS. 4A to 19B are diagrams sequentially illustrating some procedures of a manufacturing method of the semiconductor memory device according to Embodiment 1.

First, a state in which a configuration to be a part of the pillar PL and the columnar portion HR later is formed is shown in FIGS. 4A to 4C. FIGS. 4A to 4C show a cross section of the semiconductor memory device 1 under manufacturing taken along the X direction, provided with a region to be the memory region MR later and a region to be the contact region ER later. That is, the region to be the memory region MR later shown in FIGS. 4A to 4C corresponds to the cross-sectional portion taken along the A-A line in FIG. 3B described above. In addition, the region to be the contact region ER later shown in FIGS. 4A to 4C corresponds to the cross-sectional portion taken along the line A′-A′ of FIG. 3B described above.

As shown in FIG. 4A, the lower source line DSLa, the intermediate sacrificial layer SCN or the intermediate insulating layer SCO, and the upper source line DSLb are formed in this order above the supporting substrate SS.

The supporting substrate SS may be, for example, a semiconductor substrate such as a silicon substrate, an insulating substrate such as a ceramic substrate or a quartz substrate, a conductive substrate such as a sapphire substrate, or the like.

The lower source line DSLa and the upper source line DSLb are, for example, a polysilicon layer or the like. The intermediate sacrificial layer SCN is a layer that is replaced with a polysilicon layer or the like later to be an intermediate source line BSL, and is disposed in a region to be the memory region MR later. The intermediate insulating layer SCO is, for example, a silicon oxide layer or the like, and is disposed in a region to be the contact region ER later.

A stacked body LMsa in which a plurality of insulating layers NL and a plurality of insulating layers OL are alternately stacked by one layer is formed on the upper source line DSLb. The insulating layer NL is, for example, a silicon nitride layer, and functions as a sacrificial layer to be replaced with a conductive material to be the word line WL and the select gate line SGS later. The stacked body LMsa is a portion to be the stacked body LMa later by such replacement processing.

At this stage, the plurality of insulating layers OL provided with the uppermost insulating layer OL may have approximately the same thickness.

As shown in FIG. 4B, a plurality of memory holes MHa that penetrate the stacked body LMsa, the upper source line DSLb, and the intermediate sacrificial layer SCN and reach the lower source line DSLa are formed in a region to be the memory region MR later. In addition, a plurality of holes HLa that penetrate the stacked body LMsa, the upper source line DSLb, and the intermediate insulating layer SCO and reach the lower source line DSLa are formed in a region to be the contact region ER later.

These memory holes MHa and holes HLa can be formed collectively, for example. Meanwhile, the memory hole MHa and the hole HLa may be formed individually. In this case, when the memory hole MHa is formed, the region to be the contact region ER later can be protected with a resist layer or the like. In addition, when the hole HLa is formed, a region to be the memory region MR later can be protected with a resist layer or the like.

As shown in FIG. 4C, for example, the memory hole MHa is filled with a sacrificial layer such as an amorphous silicon layer to form a plurality of pillars PLs. In addition, for example, the inside of the hole HLa is filled with the insulating layer 54 such as a silicon oxide layer to form a plurality of columnar portions HRa.

The pillar PLs and the columnar portion HRa are individually formed. In this case, when the pillars PLs are formed, the region to be the contact region ER later can be protected with a resist layer or the like. In addition, when the columnar portion HRa is formed, a region to be the memory region MR later can be protected with a resist layer or the like.

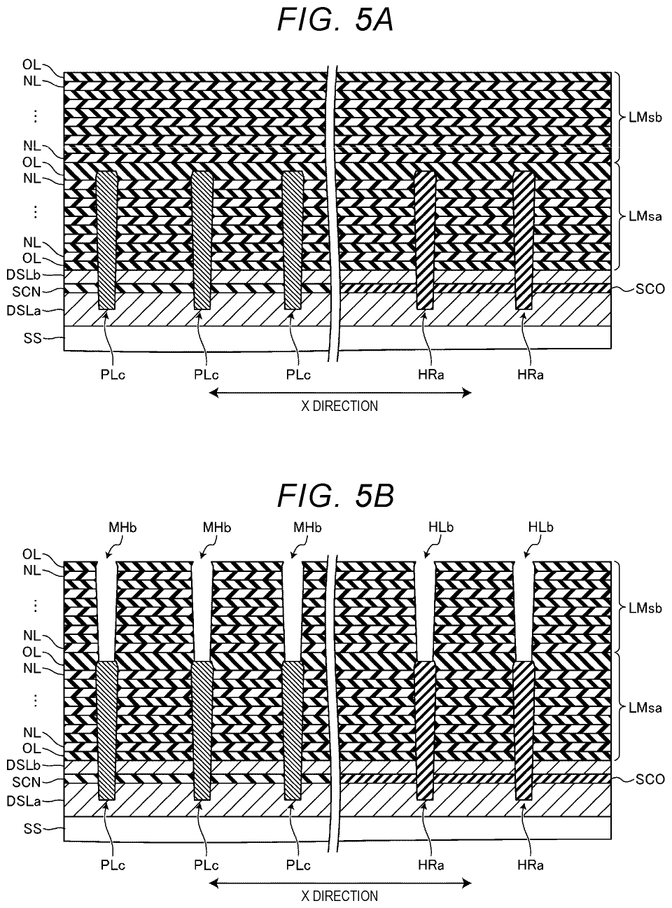

Next, a state in which the pillars PL and the columnar portions HR are formed is shown in FIGS. 5 to 7. FIGS. 5A to 7B are cross sections of the semiconductor memory device 1 under manufacturing taken along the X direction as in FIGS. 4A to 4C described above, and show cross-sectional portions corresponding to the cross section taken along the A-A line and the cross section taken along the A′-A′ line in FIG. 3B described above.

As shown in FIG. 5A, a silicon oxide layer or the like is stacked on the upper surface of the stacked body LMsa. As a result, the uppermost insulating layer OL of the stacked body LMsa is thicker than the other insulating layers OL. In addition, the upper end portions of the pillars PLs and the columnar portions HRa are buried in the uppermost insulating layer OL.

In addition, a stacked body LMsb is formed as a first stacked body in which the insulating layers NL as the plurality of first insulating layers and the insulating layers OL as the plurality of second insulating layers are alternately stacked by one layer on the stacked body LMsa. The stacked body LMsb is a portion in which the insulating layer NL is replaced with the word lines WL and the select gate lines SGD to form the stacked body LMb.

At this stage, the plurality of insulating layers OL of the stacked body LMsb provided with the uppermost insulating layer OL may have approximately the same thickness.

As shown in FIG. 5B, a plurality of memory holes MHb that penetrate the stacked body LMsb and respectively reach the upper end portions of the plurality of pillars PLa disposed in the stacked body LMsa are formed in a region to be the memory region MR later. In addition, a plurality of holes HLb that penetrate the stacked body LMsb and respectively reach the upper end portions of the plurality of columnar portions HRa disposed in the stacked body LMsa are formed in a region to be the contact region ER later.

The memory hole MHb and the hole HLb can be formed collectively, for example. Meanwhile, the memory hole MHb and the hole HLb may be formed individually while appropriately protecting a region to be the memory region MR later and a region to be the contact region ER later.

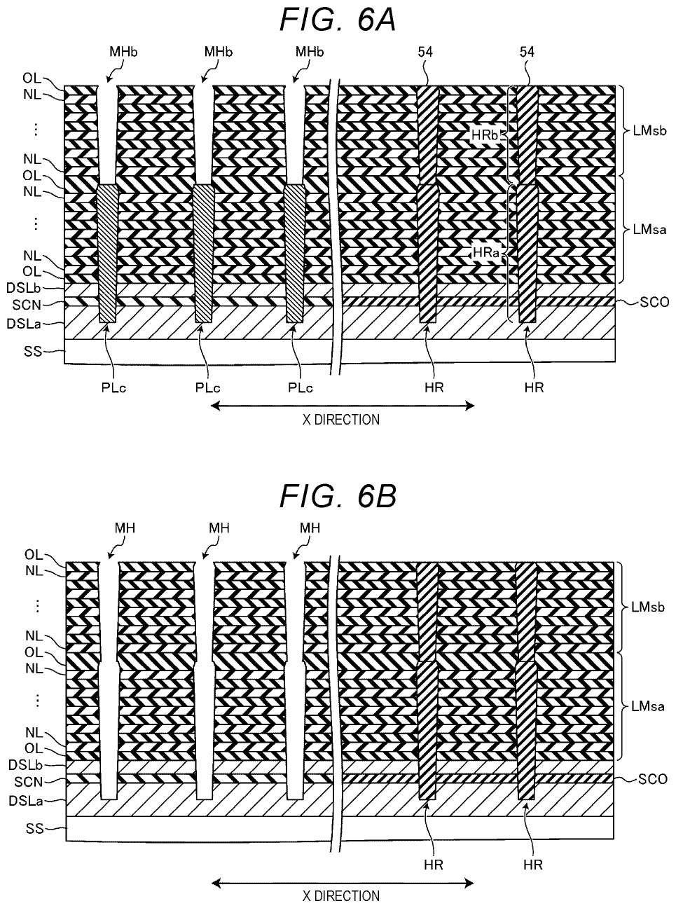

As shown in FIG. 6A, in a region to be the contact region ER later, for example, the hole HLb is filled with the insulating layer 54 such as the silicon oxide layer to form a plurality of columnar portions HRb. Accordingly, the columnar portion HR provided with the columnar portions HRa and HRb is formed.

In addition, when the columnar portion HRb is formed, a region to be the memory region MR later can be protected with a resist layer or the like.

As shown in FIG. 6B, in a region to be the memory region MR later, the sacrificial layer is removed from a plurality of pillars PLa connected to the lower end portions thereof through the plurality of memory holes MHb. As a result, a plurality of memory holes MH that penetrate the stacked bodies LMsa and LMsb and reach the source line SL are formed.

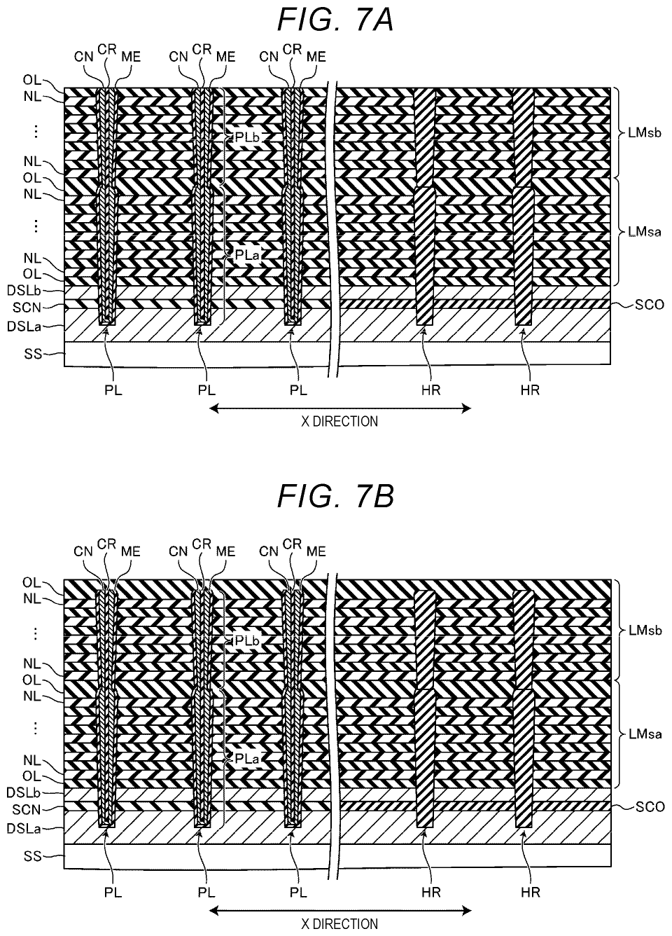

As shown in FIG. 7A, a memory layer ME having a stacked structure of the block insulating layer BK, the charge storage layer CT, and the tunnel insulating layer TN (refer to FIGS. 2B and 2C) is formed on each of a plurality of memory hole MH in order from the outer peripheral side of the memory hole MH. In addition, the channel layer CN is formed on the side walls and the lower surfaces of the plurality of memory holes MH through the memory layer ME. In addition, the voids in the memory hole MH on the inside of the channel layer CN are filled with the silicon oxide layer or the like to form the core layer CR.

At this time, the memory layer ME, the channel layer CN, and the core layer CR are also formed on the upper surface of the stacked body LMsb. The memory layer ME, the channel layer CN, and the core layer CR are removed from the upper surface of the stacked body LMsb by performing etching or the like.

As described above, the plurality of pillars PL are formed in a region to be the memory region MR later. Meanwhile, at this point, the memory layer ME covers the entire side wall of the plurality of pillars PL, and the channel layer CN is not exposed.

In addition, a plurality of columnar portions HR are formed in a region to be the contact region ER later by the processing of FIG. 6A described above. Therefore, the region to be the contact region ER later is not affected by the processing shown in FIGS. 6B and 7A.

As shown in FIG. 7B, a silicon oxide layer or the like is stacked on the upper surface of the stacked body LMsb. As a result, the uppermost insulating layer OL of the stacked body LMsb is thicker than the other insulating layers OL. In addition, the upper end portions of the pillars PL and the columnar portions HR are buried in the uppermost insulating layer OL.

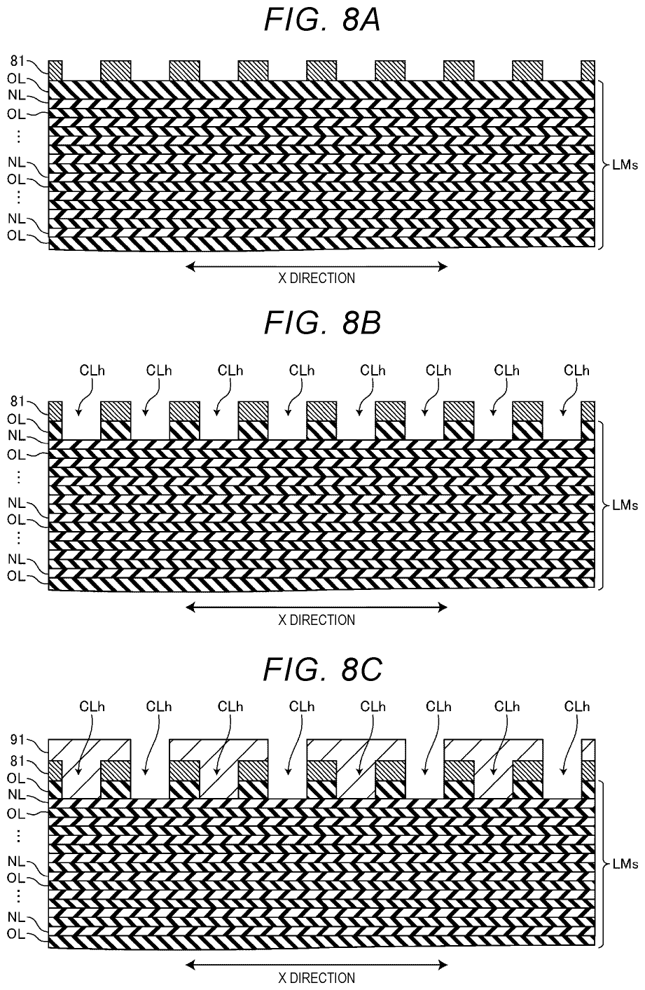

Next, a state in which a configuration to be a plurality of contacts CCs and CC later is formed will be described with reference to FIGS. 8A to 11B.

FIGS. 8A to 10C are cross sections of the contact region ER under manufacturing taken along the X direction, and show a cross section portion corresponding to the cross section taken along the B-B line in FIG. 3B described above. Meanwhile, FIGS. 8A to 10C show, as an example, an example in which the contact holes CLa to CLh that reach the depth position of each of the eight insulating layers NL of the stacked body LMs are formed. In addition, in FIGS. 8A to 10C, the plurality of columnar portions HR are not shown.

As shown in FIG. 8A, a hard mask pattern 81 having a plurality of openings is formed on the upper surface of the stacked body LMs. The hard mask pattern 81 is an inorganic layer that is not removed by ashing using, for example, oxygen plasma. Each of the plurality of openings of the hard mask pattern 81 has, for example, a hole shape.

As shown in FIG. 8B, the upper surface of the stacked body LMs exposed from the opening of the hard mask pattern 81 is etched to remove the uppermost insulating layer OL. As a result, a plurality of contact holes CLh that penetrate the uppermost insulating layer OL and reach the insulating layer NL immediately below the insulating layer OL are formed.

As shown in FIG. 8C, the patterned resist 91 that covers a part of the upper surface of the stacked body LMs via the hard mask pattern 81 and has a plurality of openings is formed. The patterned resist 91 is an organic layer such as a resist layer that may be removed by ashing using, for example, oxygen plasma. For example, the contact hole CLh is exposed every other from the opening of the patterned resist 91.

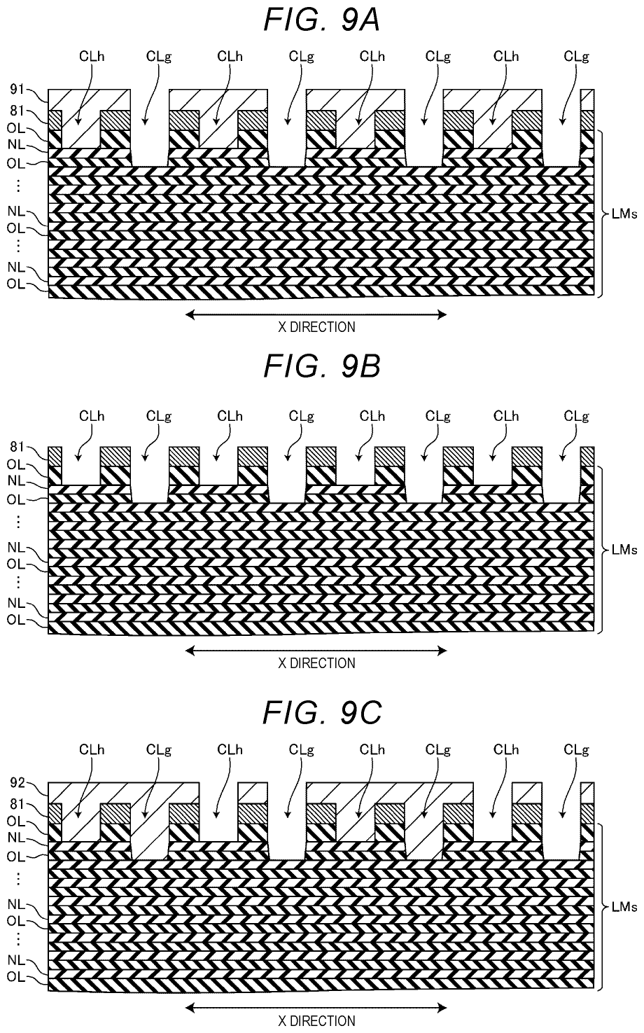

As shown in FIG. 9A, the contact hole CLh exposed from the opening of the patterned resist 91 is further etched to remove, for example, a pair of the insulating layers NL and OL from the lower surface of the contact hole CLh.

As a result, a plurality of contact holes CLg that penetrate the stacked body LMs to the second insulating layer OL from the uppermost insulating layer OL, and reach the second insulating layer NL from the uppermost insulating layer NL. The contact hole CLg is disposed every other with respect to the plurality of contact holes CLh covered with the patterned resist 91.

That is, at this stage, in the stacked body LMs, one of the plurality of contact holes CLh and the plurality of contact holes CLg are alternately formed by one hole.

As shown in FIG. 9B, the patterned resist 91 is removed by ashing using oxygen plasma or the like.

As shown in FIG. 9C, a patterned resist 92 that covers a part of the upper surface of the stacked body LMs via the hard mask pattern 81 and has a plurality of openings is formed. From the opening of the patterned resist 92, the contact hole CLh or CLg is exposed, for example, every other in one set of the contact holes CLh and CLg adjacent to each other.

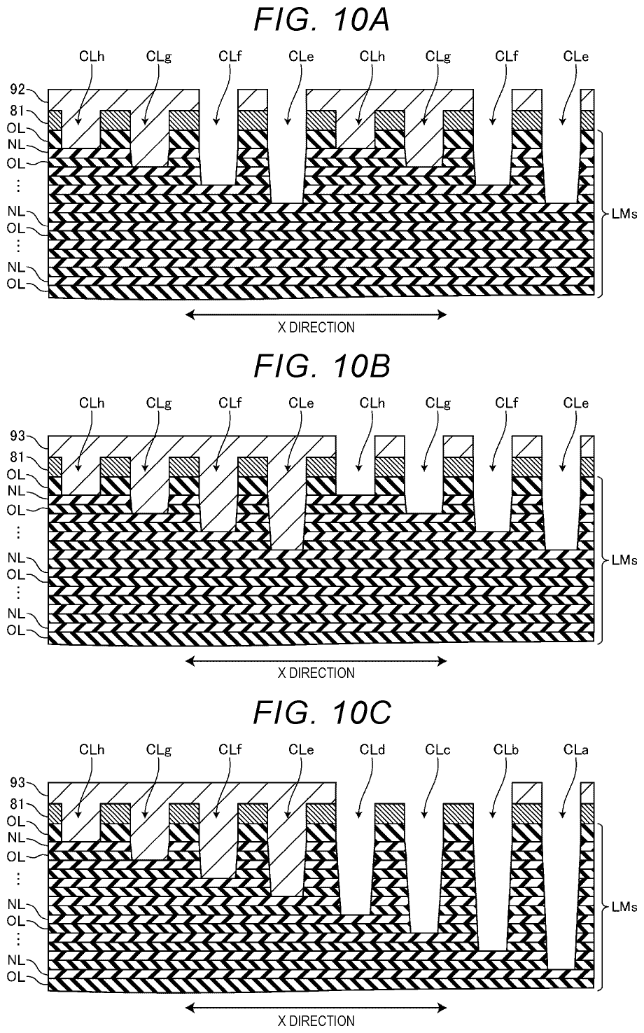

As shown in FIG. 10A, the contact holes CLh and CLg exposed from the opening of the patterned resist 92 are further etched to remove two pairs of insulating layers NL and OL from the lower surfaces of the contact holes CLh and CLg, respectively.

As a result, a plurality of contact holes CLf that penetrate the stacked body LMs to the third insulating layer OL from the uppermost insulating layer OL and reach the third insulating layer NL from the uppermost insulating layer NL are formed from the contact hole CLh that is the etching target.

In addition, a plurality of contact holes CLe that penetrate the stacked body LMs from the fourth insulating layer OL from the uppermost insulating layer OL and reach the fourth insulating layer NL from the uppermost insulating layer NL are formed from the contact hole CLg that is the etching target.

As described above, by the processing so far, two sets of the contact holes CLh to CLe in which the reaching depths of the contact holes CLh to CLe in the stacked body LMs increase in order are arranged in this order are formed.

Thereafter, the patterned resist 92 is removed by ashing using oxygen plasma or the like.

As shown in FIG. 10B, the patterned resist 93 that covers a part of the upper surface of the stacked body LMs via the hard mask pattern 81 and has a plurality of openings is formed. From the opening of the patterned resist 93, one set of contact holes CLh to CLe is exposed out of the two sets of contact holes CLh to CLe.

As shown in FIG. 10C, the contact holes CLh to CLe exposed from the opening of the patterned resist 93 are further etched to remove, for example, four pairs of insulating layers NL and OL from the lower surfaces of the contact holes CLh to CLe.

Accordingly, the contact hole CLd that penetrates the stacked body LMs from the fifth insulating layer OL from the uppermost insulating layer OL and reaches the fifth insulating layer NL from the uppermost insulating layer NL is formed from the contact hole CLh that is the etching target.

In addition, the contact hole CLc that penetrates the stacked body LMs to the sixth insulating layer OL from the uppermost insulating layer OL and reaches the sixth insulating layer NL from the uppermost insulating layer NL is formed from the contact hole CLg that is the etching target.

In addition, the contact hole CLb that penetrates the stacked body LMs to the seventh insulating layer OL from the uppermost insulating layer OL and reaches the seventh insulating layer NL from the uppermost insulating layer NL is formed from the contact hole CLf that is the etching target.

In addition, the contact hole CLa that penetrates the stacked body LMs to the eighth insulating layer OL from the uppermost insulating layer OL and reaches the eighth insulating layer NL from the uppermost insulating layer NL is formed from the contact hole CLe that is the etching target.

As described above, a plurality of the contact holes CLh to CLa in which the reaching depths in the stacked body LMs increase in order and which respectively reach the eight insulating layers NL in the stacked body LMs are formed. Thereafter, the patterned resist 93 is removed by ashing using oxygen plasma or the like. In addition, the hard mask pattern 81 is removed by etching or the like.

The one or more insulating layers NL including the uppermost insulating layer NL are layers to be the select gate line SGD later. Therefore, among the plurality of contact holes CLh to CLa, the contact holes reaching these insulating layers NL are formed to be smaller than the contact holes reaching the insulating layers NL lower than these insulating layers NL. In order to make the diameters of the contact holes CLh to CLa different from each other, for example, in the processing of FIG. 8A described above, some of the diameters of the plurality of openings of the hard mask pattern 81 need only be formed to be smaller than the other openings.

Meanwhile, instead of collectively forming the plurality of contact holes CLh to CLa having different diameters, contact holes having a smaller diameter than the others may be separately formed. Accordingly, any of the contact holes CLh to CLa can be formed with high accuracy. When the contact holes are separately made for each different diameter, the processing of FIGS. 8A to 10C described above can be repeated a plurality of times while appropriately protecting the region in which each contact hole is formed with a resist layer or the like.

As described above, among the plurality of contact holes CLh to CLa, the contact hole that has a smaller diameter than the other contact holes and reaches one or more insulating layers NL including the uppermost insulating layer NL is an example of the first contact hole. In addition, among the plurality of contact holes CLh to CLa, the contact hole reaching the insulating layer NL lower than the one or more insulating layers NL including the uppermost insulating layer NL is an example of the second contact hole.

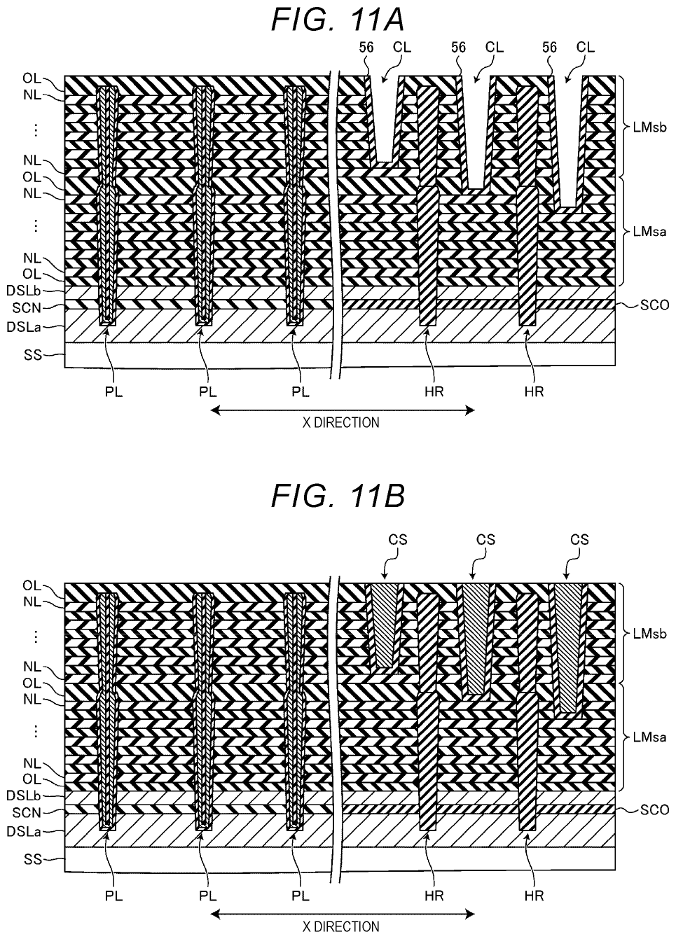

FIG. 11 is a cross section of the semiconductor memory device 1 under manufacturing taken along the X direction, as in FIGS. 5A to 7B and the like described above, and shows cross-sectional portions corresponding to the cross section taken along the A-A line and the cross section taken along the A′-A′ line in FIG. 3B described above. By the processing of FIGS. 8A to 10C described above, a plurality of contact holes are formed in a region to be the contact region ER later.

FIG. 11A shows contact holes CL that respectively reach the fifth and fourth insulating layers NL from the lowermost layer of the stacked body LMsb and the lowermost layer of the stacked body LMsa among the plurality of contact holes respectively reaching the different insulating layers NL in the stacked bodies LMsa and LMsb.

Meanwhile, the plurality of contact holes CL may be formed at positions overlapping with a part of the plurality of columnar portions HR, regardless of the example shown in FIG. 11A. In this case, a portion where the contact hole of the columnar portion HR is formed may be in a state of being missing.

As shown in FIG. 11A, an insulating layer 56 covering the side walls and the lower surface of each of the plurality of contact holes CL is formed. The insulating layer 56 is, for example, a silicon oxide layer or the like.

As shown in FIG. 11B, each of the plurality of contact holes CL is filled with a sacrificial layer such as an amorphous silicon layer through the insulating layer 56. As a result, a plurality of columnar bodies CS are formed. These columnar bodies CS are contact-like temporary structures provided with a sacrificial layer.

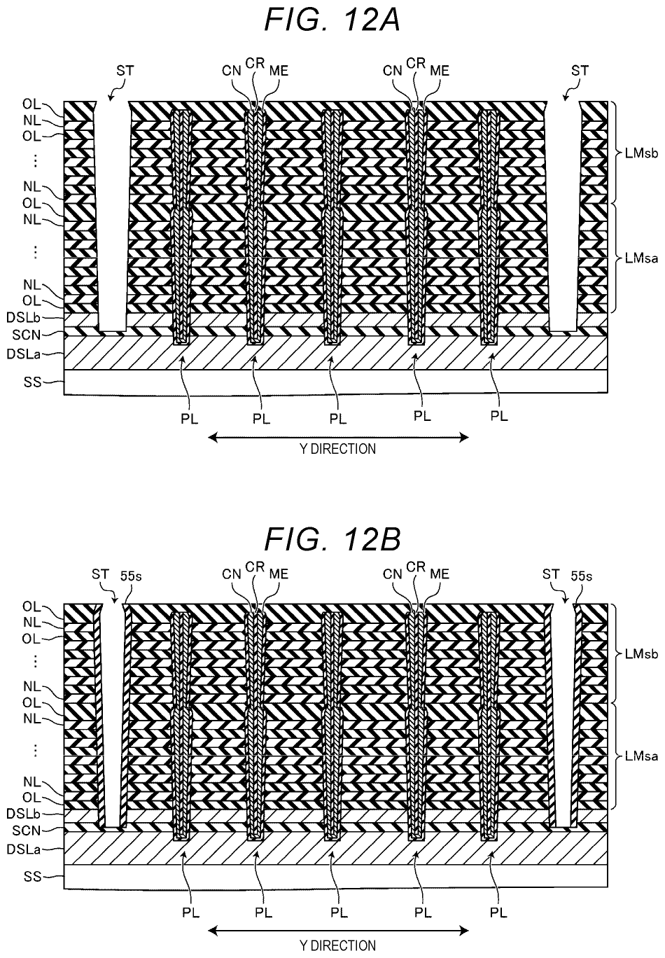

Next, a states in which the source line SL and the word line WL are formed will be shown with reference to FIGS. 12A to 16B. FIGS. 12A to 16B are cross-sectional views taken along the Y direction of a region to be the memory region MR later, and are cross-sectional portions corresponding to the cross-section taken along the C-C line in FIG. 3B described above.

As shown in FIG. 12A, a slit ST that penetrates the stacked bodies LMsa and LMsb and the upper source line DSLb and reaches the intermediate sacrificial layer SCN is formed.

The slit ST also extends in the direction along the X direction in the stacked bodies LMsa and LMsb, that is, in the direction perpendicular to the plane of the drawing. Therefore, in the region to be the contact region ER later, the lower end portion of the slit ST reaches the intermediate insulating layer SCO. The slit ST is used for a replacement processing described below and will be a plate-shaped contact LI later.

As shown in FIG. 12B, the insulating layers 55s are formed on the side walls of the slit ST facing each other in the Y direction. The insulating layer 55s is, for example, a silicon oxide layer or the like, and is a temporary protective layer that is different from the insulating layer 55 described above (refer to FIG. 2A) to be provided on the side wall of the plate-shaped contact LI later, and is formed to protect the stacked bodies LMsa and LMsb in the subsequent processing.

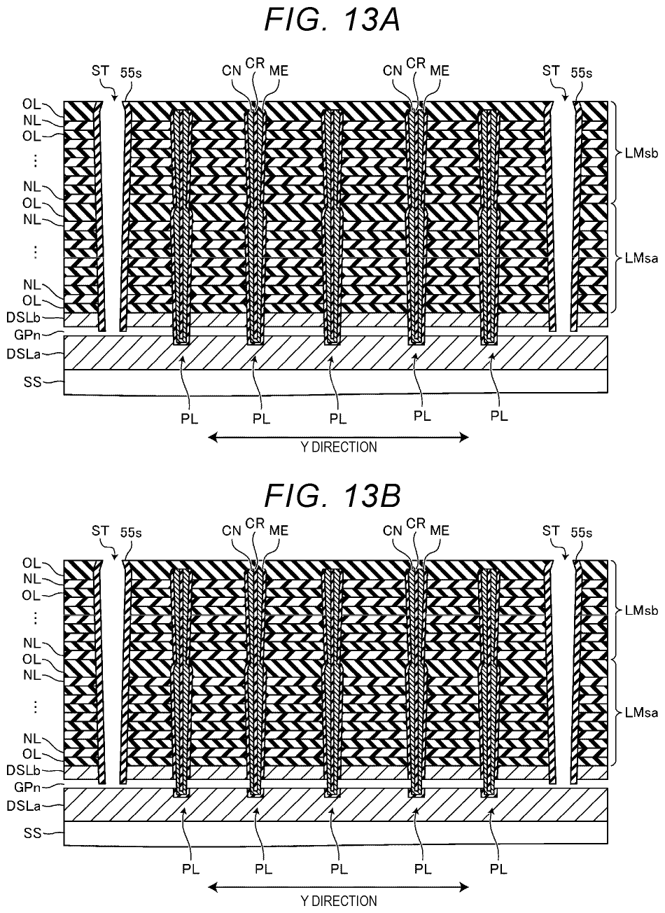

As shown in FIG. 13A, for example, a removal liquid for the intermediate sacrificial layer SCN such as hot phosphoric acid is caused to flow through the slit ST of which the side wall is protected by the insulating layer 55s to remove the intermediate sacrificial layer SCN sandwiched between the lower source line DSLa and the upper source line DSLb.

Accordingly, the gap layer GPn is formed between the lower source line DSLa and the upper source line DSLb. In addition, a part of the memory layer ME in the outer peripheral portion of the pillar PL is exposed in the gap layer GPn.

At this time, since the side wall of the slit ST is protected by the insulating layer 55s, the insulating layer NL in the stacked bodies LMsa and LMsb is prevented from being also removed.

As shown in FIG. 13B, a chemical solution is appropriately flowed into the gap layer GPn through the slit ST to subsequently remove the block insulating layer BK, the charge storage layer CT, and the tunnel insulating layer TN (refer to FIGS. 2B and 2C) of the memory layer ME exposed in the gap layer GPn. Accordingly, the memory layer ME is removed from a part of the side wall of the pillar PL, and a part of the inner channel layer CN is exposed in the gap layer GPn.

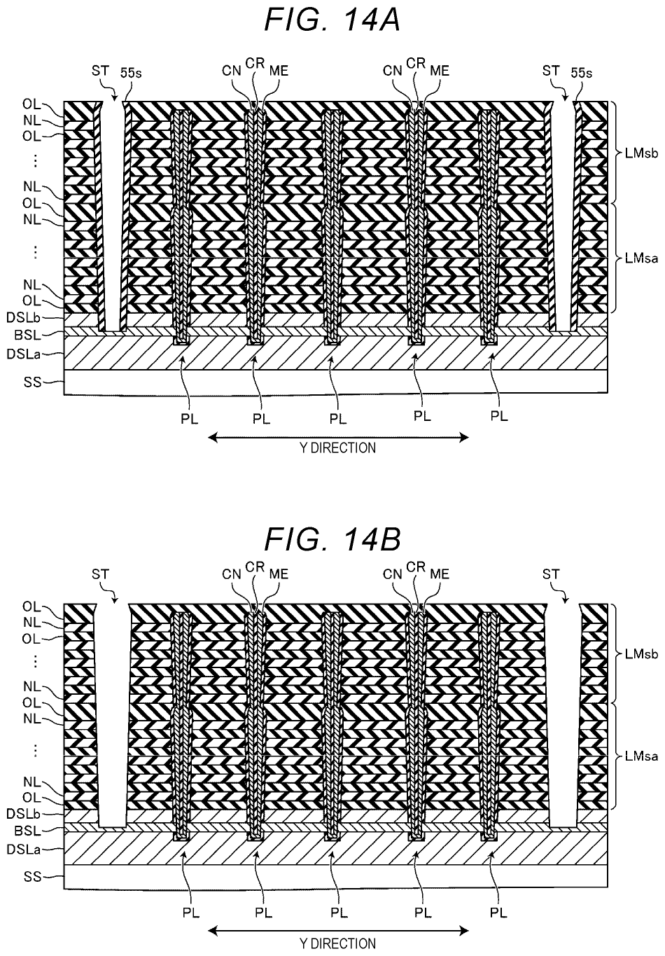

As shown in FIG. 14A, for example, a raw material gas such as amorphous silicon is injected from the slit ST of which the side wall is protected by the insulating layer 55s, and the gap layer GPn is filled with amorphous silicon or the like. In addition, the supporting substrate SS is heat-treated to polycrystallize the amorphous silicon provided in the gap layer GPn, thereby forming the intermediate source line BSL containing polysilicon or the like.

Accordingly, a part of the channel layer CN of the pillar PL is connected to the source line SL on the side surface through the intermediate source line BSL.

As shown in FIG. 14B, the insulating layer 55s is removed from the side wall of the slit ST.

In the region to be the contact region ER later, the intermediate insulating layer SCO is formed between the lower source line DSLa and the upper source line DSLb instead of the intermediate sacrificial layer SCN. Therefore, the region to be the contact region ER later is not affected by the processing shown in FIGS. 13A to 14B described above.

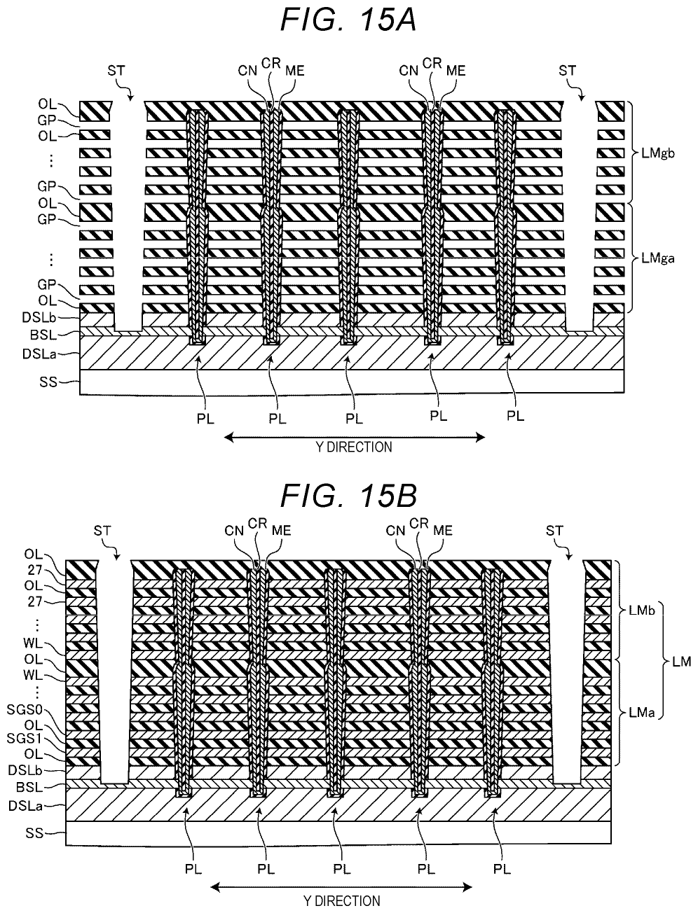

As shown in FIG. 15A, for example, a removal liquid of the insulating layer NL such as phosphoric acid is caused to flow from the slit ST into the stacked bodies LMsa and LMsb, and the insulating layer NL of the stacked bodies LMsa and LMsb is removed. As a result, the stacked bodies LMga and LMgb having a plurality of gap layers GP from which the insulating layer NL between the insulating layers OL is removed are formed.

The stacked bodies LMga and LMgb provided with the plurality of gap layers GP have a fragile structure. In the region to be the memory region MR later, the plurality of pillars PL support the fragile stacked bodies LMga and LMgb. Meanwhile, in the region to be the contact region ER later, the plurality of columnar portions HR support the stacked bodies LMga and LMgb.

With the support structure of the pillar PL and the columnar portion HR, the remaining insulating layer OL is prevented from being bent, and the stacked bodies LMga and LMgb itself are prevented from being distorted or collapsing.

As shown in FIG. 15B, for example, a raw material gas of a conductive material such as tungsten or molybdenum is injected from the slit ST into the stacked bodies LMga and LMgb, and the gap layers GP of the stacked bodies LMga and LMgb are filled with the conductive material to form a plurality of word lines WL and the like.

As a result, the stacked body LM provided with the stacked body LMa in which the plurality of word lines WL or the like and the plurality of insulating layers OL are alternately stacked by one layer and a stacked body LMb as a second stacked body is formed. Meanwhile, at this point, the separation layers SHEh and SHEv are not formed, and the one or more conductive layers 27 provided with the uppermost conductive layer 27 of the stacked body LMb are not the select gate lines SGD separated into a plurality of sections.

As described above, the processing of forming the intermediate source line BSL from the intermediate sacrificial layer SCN and the processing of forming the word line WL from the insulating layer NL are also referred to as replacement processing.

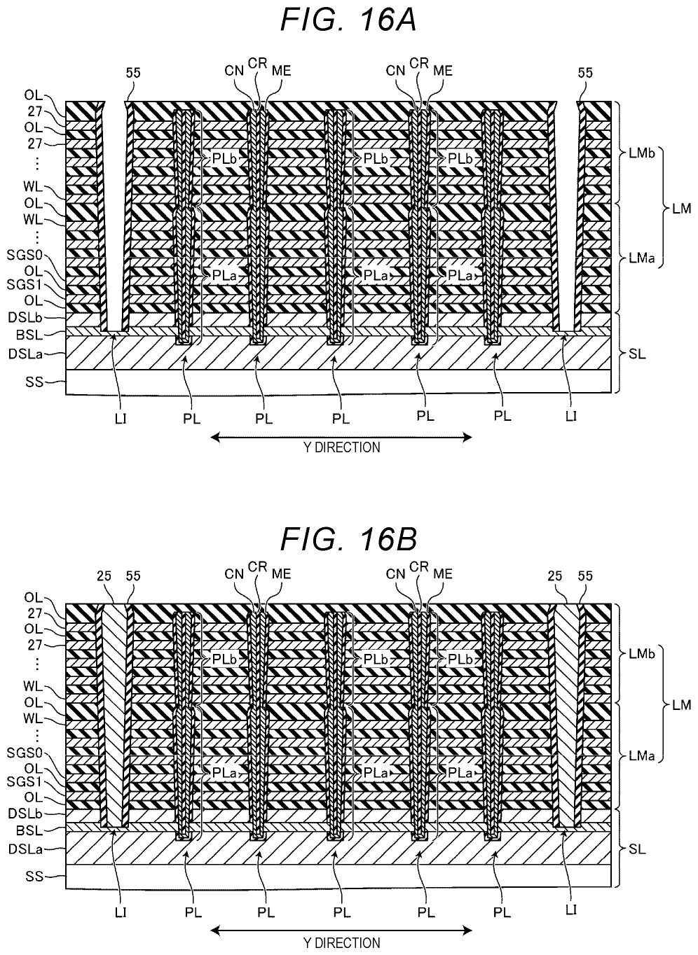

As shown in FIG. 16A, the insulating layer 55 is formed on the side wall of the slit ST.

As shown in FIG. 16B, the insulating layer 55 is filled with the conductive layer 25 to form a plate-shaped contact LI serving as a source line contact. Meanwhile, the slit ST may be filled with the insulating layer 55 or the like without forming the conductive layer 25 to form a plate-shaped member having no function as a source line contact.

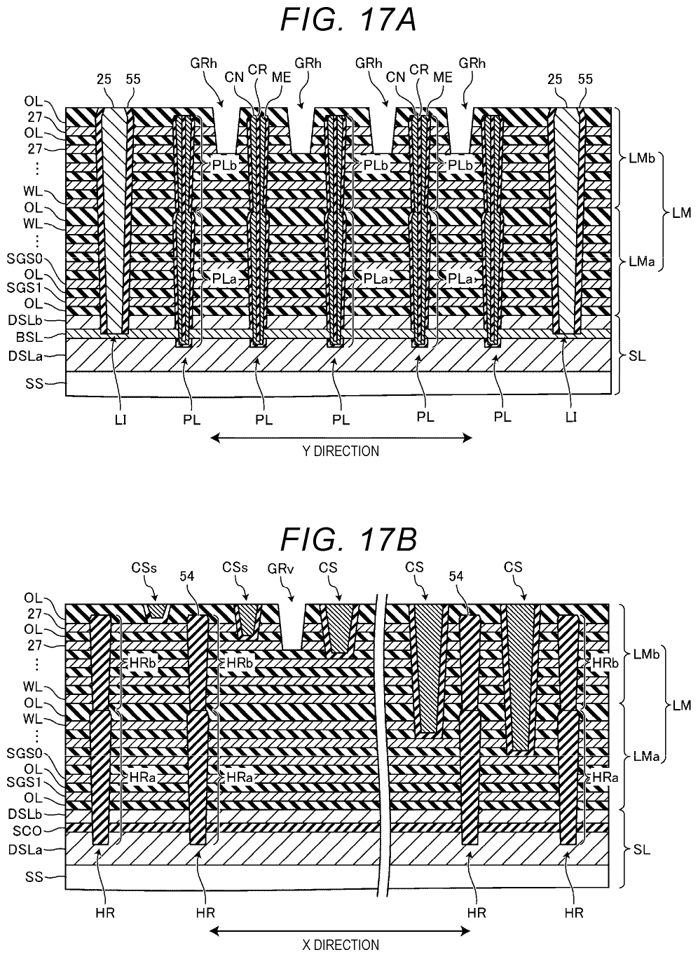

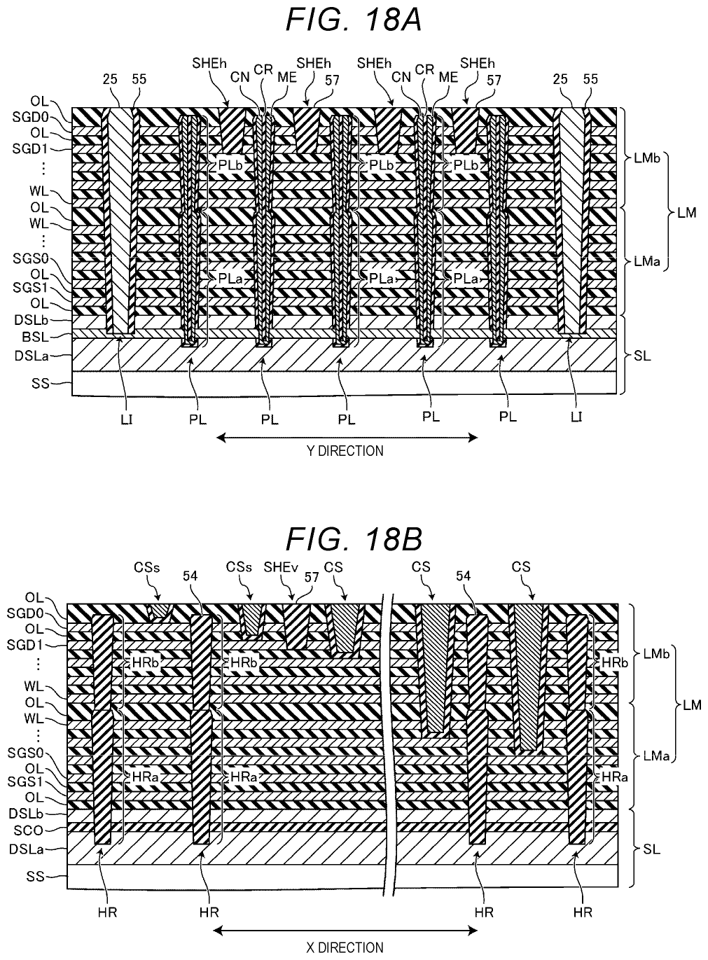

Next, a state in which the conductive layer 27 of the upper layer of the stacked body LMb is separated into the plurality of sections of select gate lines SGD by the separation layers SHEh and SHEv will be shown with reference to FIGS. 17A to 18B.

FIGS. 17A and 18A are cross-sectional views taken along the Y direction of a region to be the memory region MR later, as in FIGS. 12A to 16B, and are cross-sectional portions corresponding to the cross section taken along the line C-C in FIG. 3B described above. FIGS. 17B and 18B are cross-sectional views taken along the region to be the contact region ER later in the X direction, and are cross-sectional portions corresponding to the cross section taken along the line D-D in FIG. 3B described above.

FIG. 17B shows the columnar body CS connected to each of the third word line WL from the lowermost layer, the word line WL of the lowermost layer, and the second word line WL from the lowermost layer of the stacked body LMb. In addition, a columnar body CSs shown in FIG. 17B is a contact-like temporary structure respectively connected to one or more conductive layers 27 provided with the uppermost conductive layer 27 of the stacked body LMb and provided with a sacrificial layer.

As shown in FIG. 17, a plurality of grooves GRh and GRv that penetrate one or more conductive layers 27 provided with the uppermost conductive layer 27 of the stacked body LMb and reach the insulating layer OL immediately below are formed.

The plurality of grooves GRh extend in the direction along the X direction in the region to be the memory region MR later and the region to be the contact region ERd later. The groove GRv extends in the direction along the Y direction between the region to be the contact region ERd later and the region to be the contact region ERw later. The groove GRv is connected to the plurality of grooves GRh on the side surface and is connected to each of the plate-shaped contacts LI adjacent to each other in the Y direction at both end portions in the extension direction.

As shown in FIG. 18, the plurality of grooves GRh and GRv are filled with the insulating layer 57 such as a silicon oxide layer. Accordingly, a plurality of separation layers SHEh in which the plurality of grooves GRh are filled with the insulating layer 57 are formed. In addition, the separation layer SHEv in which the groove GRv is filled with the insulating layer 57 is formed.

As described above, one or more conductive layers 27 provided with the uppermost conductive layer 27 of the stacked body LMb are partitioned into the pattern of the select gate line SGD.

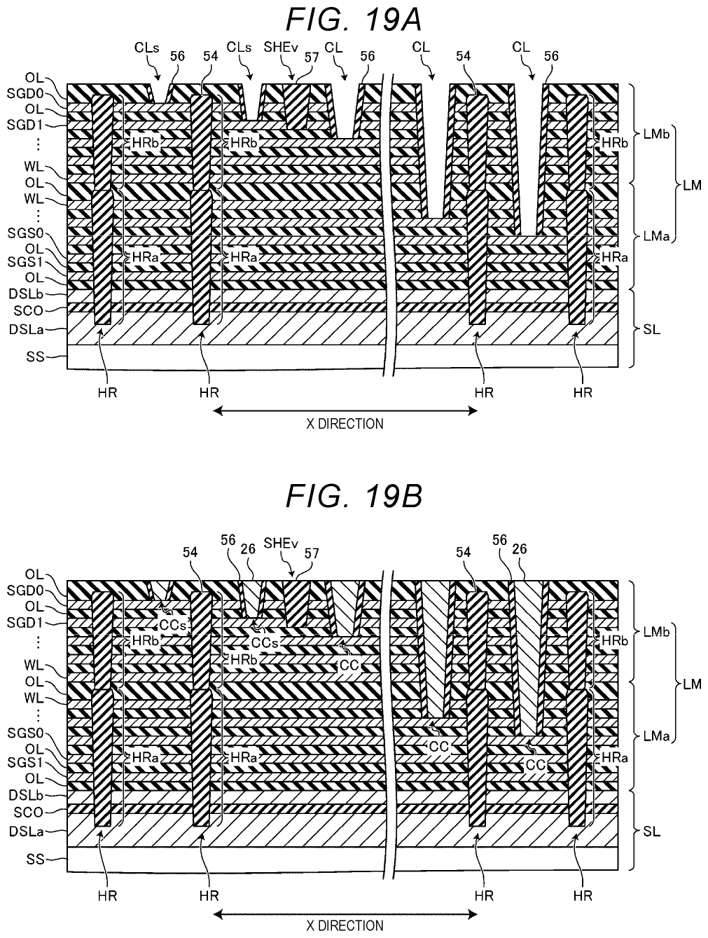

Next, a state in which a plurality of contacts CCs and CC are formed will be shown with reference to FIG. 19. FIG. 19 is a cross-sectional view taken along X direction of a region to be the contact region ER later, as in FIGS. 17A to 18B described above, and is a cross-sectional portion corresponding to the cross section taken along the D-D line in FIG. 3B described above.

As shown in FIG. 19A, the sacrificial layers are removed from the plurality of columnar bodies CSs and CS to form a plurality of contact holes CLs and CL. The contact hole CLs reaches each of the select gate lines SGD and will be a contact CCs later.

In addition, the insulating layer 56 covering the lower surfaces of the plurality of contact holes CLs and CL is removed. Accordingly, a plurality of contact holes CLs and CL in which each of the side walls is covered with the insulating layer 56 are formed.

As shown in FIG. 19B, the plurality of contact holes CLs and CL covered with the insulating layer 56 are filled with the conductive layers 26 such as tungsten layers. As a result, a plurality of contacts CCs and CC are formed.

Thereafter, the insulating layer 52 is formed on the upper surface of the stacked body LMb, and the plugs CH and V0 penetrating the insulating layer 52 are formed. The plugs CH and V0 are respectively connected to the pillar PL and the upper end portions of the contacts CCs and CC. In addition, an insulating layer 53 is formed on the insulating layer 52, and the bit line BL and the upper-layer wiring MX are formed on the insulating layer 53. The bit line BL is connected to the pillar PL via the plug CH, and the upper-layer wiring MX is connected to the contacts CCs and CC via the plug V0.

For example, the plug CH and the bit line BL, and the plug V0 and the upper-layer wiring MX may be collectively formed by using a dual damascene method or the like.

In addition, the electrode pads PDb that are connected to the bit lines BL and the upper-layer wiring MX are formed.

Meanwhile, the peripheral circuit CBA is formed on the semiconductor substrate SB, which is a separate body from the supporting substrate SS on which the stacked body LM is formed, and is covered with the insulating layer 40. In the insulating layer 40, a contact, a via, a wiring, or the like for drawing out the peripheral circuit CBA to the surface of the insulating layer 40 is formed, and the contact, the via, the wiring, or the like is connected to the electrode pad PDc or the like formed on the surface of the insulating layer 40.

In addition, the supporting substrate SS and the semiconductor substrate SB are bonded to each other by the insulating layers 50 and 40 that are respectively provided in the supporting substrate SS and the semiconductor substrate SB, and the electrode pads PDb and PDc in the insulating layers 50 and 40 are connected to each other. Thereafter, the supporting substrate SS is ground and removed to expose the source line SL, and the electrode film EL is connected via the insulating layer 60 in which the plug PG is formed.

As described above, the semiconductor memory device 1 of Embodiment 1 is manufactured.

### Overview

A semiconductor memory device such as a three-dimensional non-volatile memory has a configuration in which memory cells are formed in three dimensions in a stacked body in which, for example, a plurality of word lines and select gate lines are stacked. In order to draw out these word lines and select gate lines to upper-layer wirings and the like, contacts connected to individual word line and individual select gate line are disposed.

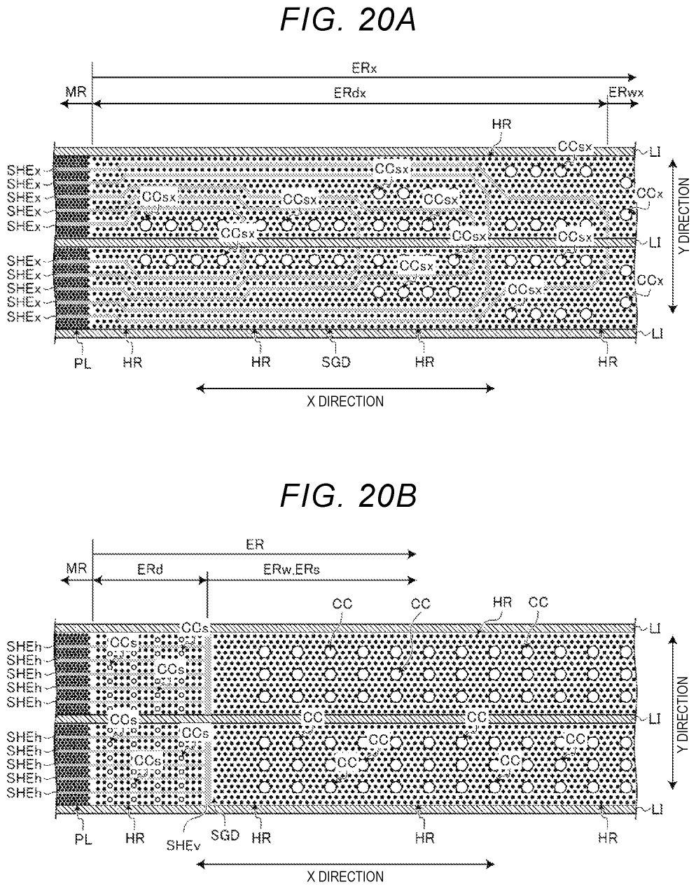

Meanwhile, as the number of layers of the word line and the select gate line increases, the area of the contact region in which a plurality of contacts are disposed increases, and there is a concern that the semiconductor memory device may be enlarged. In addition, the select gate line is separated into a plurality of regions by a separation layer or the like. Therefore, when the number of layers of the select gate line increases, there is also a concern that the partitioning of the select gate line by the separation layer may be complicated. FIGS. 20A and 20B show an example of a semiconductor memory device of a comparative example.

FIGS. 20A and 20B are XY cross-sectional views including the contact regions ER and ERx at the height position of the select gate line SGD provided in the semiconductor memory device according to Embodiment 1 and the comparative example. FIG. 20A is a configuration example of a semiconductor memory device of the comparative example, and FIG. 20B is redisplaying of FIG. 3B of the above-described Embodiment 1. In FIGS. 20A and 20B, in the semiconductor memory devices of Embodiment 1 and the comparative example, as in the example of FIG. 3B described above, both the semiconductor memory devices have four select gate lines SGD, and the select gate lines SGD are separated into six regions.

As shown in FIG. 20A, in the contact region ERx of the comparative example, the plurality of contacts CCsx connected to the select gate line SGD and the plurality of contacts CCx connected to the word line or the like of the lower layer are respectively disposed in the contact regions ERdx and ERwx disposed in the direction away from the memory region MR.

In addition, in the comparative example, the plurality of contacts CCsx are configured in the same manner as the plurality of contacts CCx and have a relatively large diameter.

Therefore, in order to separate each of the four layers of select gate lines SGD into six regions between the plate-shaped contacts LI, and to arrange a total of 24 contacts CCsx connected to the four layers of select gate lines SGD in each of the regions, the design of the separation layer SHEx has no choice but to be complicated, and the arrangement of the contacts CCsx also has no choice but to be complicated.

In the example in FIG. 20A, the five separation layers SHEx that separate the select gate line SGD into six regions in the region between the plate-shaped contacts LI generally extend in the X direction in the contact region ERdx in which the contacts CCsx are disposed, and are connected to the plate-shaped contact LI from the side surface to be terminated in the order of the separation layers SHEx disposed at positions close to the one plate-shaped contact LI.

Due to the complicated design and arrangement as described above, the area of the contact region ERdx is increased, the margin in the lithography for implementing the complicated design as described above is reduced, and the processing difficulty in the contact region ERdx is increased.

As shown in FIG. 20B, in Embodiment 1, the plurality of contacts CCs connected to the select gate line SGD have a diameter smaller than that of the plurality of contacts CC connected to the word line WL and the like of the lower layer, as described above.

As described above, the reason why the diameter of the contact CCs can be reduced is that, unlike the contact CC connected to the target word line WL or the like by penetrating a plurality of word lines WL or the like, the contact CCs connected to the select gate line SGD at a relatively shallow position are more likely to secure the breakdown voltage against the select gate line SGD or the like which is not to be connected.

By reducing the diameter of the contact CCs, the separation layer SHEh extending in the direction along the X direction and the separation layer SHEv extending in the direction along the Y direction are used to separate the select gate line SGD into a plurality of regions with a relatively simple design. In addition, the contacts CCs can also be disposed relatively simply, for example, in a grid shape arranged in the X direction and the Y direction.

As a result, in the example of FIGS. 20A and 20B, the area of the contact region ERd of Embodiment 1 can be reduced by about 80% as compared with the area of the contact region ERdx of the comparative example.

According to the semiconductor memory device 1 of Embodiment 1, the contact CCs extending from the upper side of the stacked body LM and connected to any one of the one or more select gate lines SGD, and the contact CC extending from the upper side of the stacked body LM and connected to any one of the one or more word lines WL lower than the one or more select gate lines SGD, and having a diameter, which is larger than that of the upper surface of the contact CCs, on the upper surface are provided.

As a result, the select gate line SGD can be separated into a plurality of regions by the separation layers SHEh and SHEv having the simple design, and the plurality of contacts CCs can be simply and densely disposed. Therefore, the contact region ERd in which the plurality of contacts CCs are disposed can be reduced, and the size of the semiconductor memory device 1 can be reduced. In addition, the margin in the lithography when processing the contact region ERd is reduced, and the processing difficulty in the contact region ERd can be reduced.

According to the semiconductor memory device 1 of Embodiment 1, the separation layer SHEv that penetrates the select gate line SGD and extends in the direction along the Y direction in the stacked body LM at a position between the plurality of contacts CCs and CC, and selectively separates the select gate line SGD into the contact CCs side and the contact CC side is provided.

In this way, by arranging the plurality of separation layers SHEh extending in the direction along the X direction in the stacked body LM and the separation layer SHEv extending in the direction along the Y direction in the stacked body LM, the select gate line SGD of the semiconductor memory device 1 can be separated into a plurality of regions.

### Modification Example 1

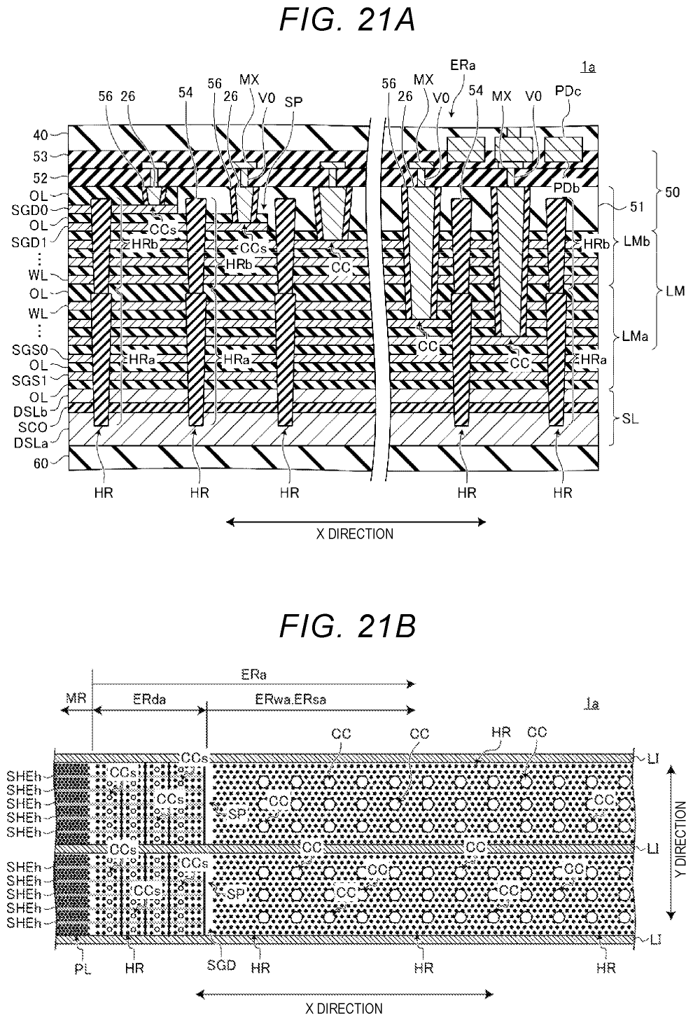

Next, a semiconductor memory device 1a of Modification Example 1 of Embodiment 1 will be described with reference to FIGS. 21A to 27C. The semiconductor memory device 1a of Modification Example 1 is different from Embodiment 1 described above in that the select gate line SGD is processed in a stepped shape.

In the following drawings, the same reference numerals are given to the same configurations as in Embodiment 1, and the description thereof may be omitted.

FIGS. 21A and 21B are diagrams showing an example of a configuration of the semiconductor memory device 1a according to Modification Example 1 of Embodiment 1. More specifically, FIG. 21A is a cross-sectional view taken along the X direction showing an example of the configuration of the contact region ERa. FIG. 21B is an XY cross-sectional view including the contact region ERa at the height position of the select gate line SGD.

Meanwhile, in FIG. 21A, the structure below the insulating layer 60 and the structure above the insulating layer 40 are not shown. In addition, the number, the arrangement, and the like of each configuration in the cross-sectional view in the Y direction of FIG. 21A and those in the XY cross-sectional view of FIG. 21B do not necessarily match.

As shown in FIG. 21, the semiconductor memory device 1a is provided with a stepped part SP as a first stepped part in which the select gate line SGD of the stacked body LMb is processed in a stepped shape. More specifically, the select gate line SGD of the stacked body LMb is processed in a stepped shape in which the height position of the terrace surface is lowered as the select gate line SGD is farther from the memory region MR, and is terminated in the vicinity of the connection portion with each contact CCs.

Therefore, the contact region ERa of Modification Example 1 is provided with the contact region ERda having the stepped part SP in which the select gate line SGD is processed in a stepped shape and the contact regions ERwa and ERsa in which the insulating layer OL immediately above the uppermost word line WL among the plurality of word lines WL is the uppermost layer of the stacked body LMb.

Also in Modification Example 1, the select gate line SGD is separated into a plurality of regions by the separation layer SHEh extending in the direction along the X direction, as in Embodiment 1 described above. Meanwhile, since the select gate line SGD is processed in a stepped shape and is terminated in the contact region ERda, the semiconductor memory device 1a of Modification Example 1 does not have the separation layer SHEv extending in the direction along the Y direction.

The contact regions ERda, ERwa, and ERsa are covered with the insulating layer 51 that reaches the height position of the upper surface of the unprocessed portion of the stacked body LMb. The insulating layer 51 is, for example, a silicon oxide layer or the like. The above-mentioned insulating layers 52 and 53 covering the upper surface of the stacked body LM also cover the upper surface of the insulating layer 51.

A plurality of contacts CCs, which penetrates the insulating layer 51 and the insulating layer OL forming the terrace surface of the stepped part SP to respectively reach the select gate lines SGD to be connected, are disposed in the contact region ERda. That is, the contact CCs are connected to the select gate line SGD on each of the terrace surfaces processed in a stepped shape. In the example of FIG. 21B, the semiconductor memory device 1a has four layers of select gate lines SGD, these are processed into a four-stage stepped part SP, and the contact CCs is disposed in each stage.

The plurality of contacts CCs extend only in the insulating layer 51 above the stacked body LM and do not penetrate the word line WL and the like of the stacked body LM. Therefore, the side walls of the contact CCs may not be covered with the insulating layer 56.

A plurality of contacts CC, which penetrate the insulating layer 51 and the stacked body LM of the word line WL portion excluding the select gate line SGD to respectively reach the word line WL and the select gate line SGS to be connected, are disposed in the contact regions ERwa and ERsa.

The semiconductor memory device 1a of Modification Example 1 as described above can be manufactured as follows.

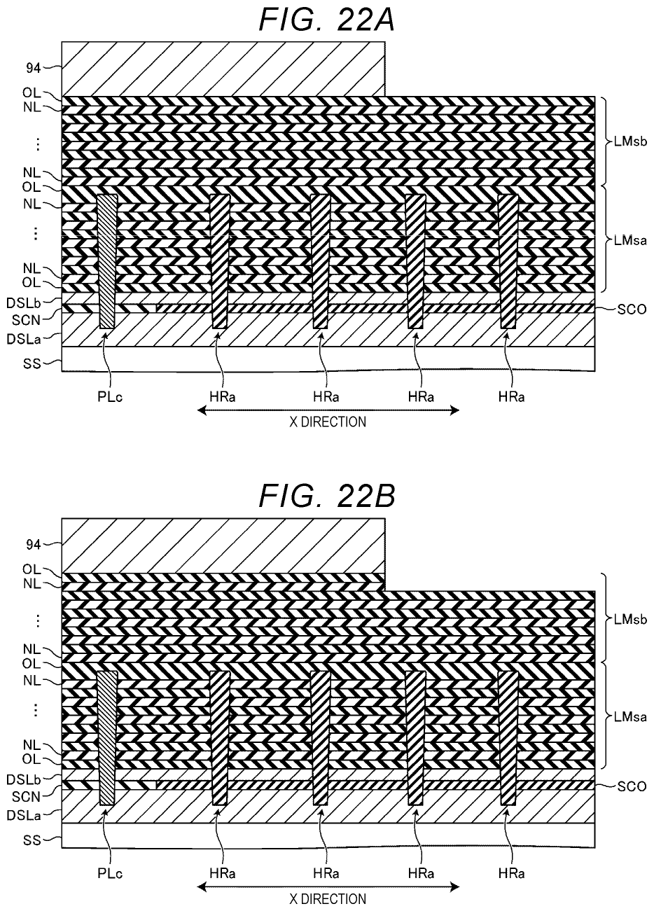

FIGS. 22A to 26B are diagrams sequentially illustrating some procedures of the manufacturing method of the semiconductor memory device 1a according to Modification Example 1 of Embodiment 1.

In the semiconductor memory device 1a of Modification Example 1, the same processing as the processing shown in FIGS. 4A to 5A of Embodiment 1 described above is performed. FIGS. 22A to 26B show the state of the subsequent processing.

FIGS. 22A to 26B show cross sections of the semiconductor memory device 1a under manufacturing along the X direction, including a region to be the memory region MR later and a region to be the contact region ERa later.

As shown in FIG. 22A, by the processing so far, the lower source line DSLa and the upper source line DSLb provided with the intermediate sacrificial layer SCN or the intermediate insulating layer SCO in between, the stacked body LMsa and LMsb, and the pillar PLc and the columnar portion HRa penetrating the stacked body LMsa are formed on the supporting substrate SS.

In addition, the patterned resist 94 that covers a part of the upper surface of the stacked body LMsb is formed. The patterned resist 94 has an end portion in a portion to be the lowermost stage of the stepped part SP later.

As shown in FIG. 22B, for example, a pair of insulating layers NL and OL are removed from the upper surface of the stacked body LMsb exposed from the patterned resist 94.

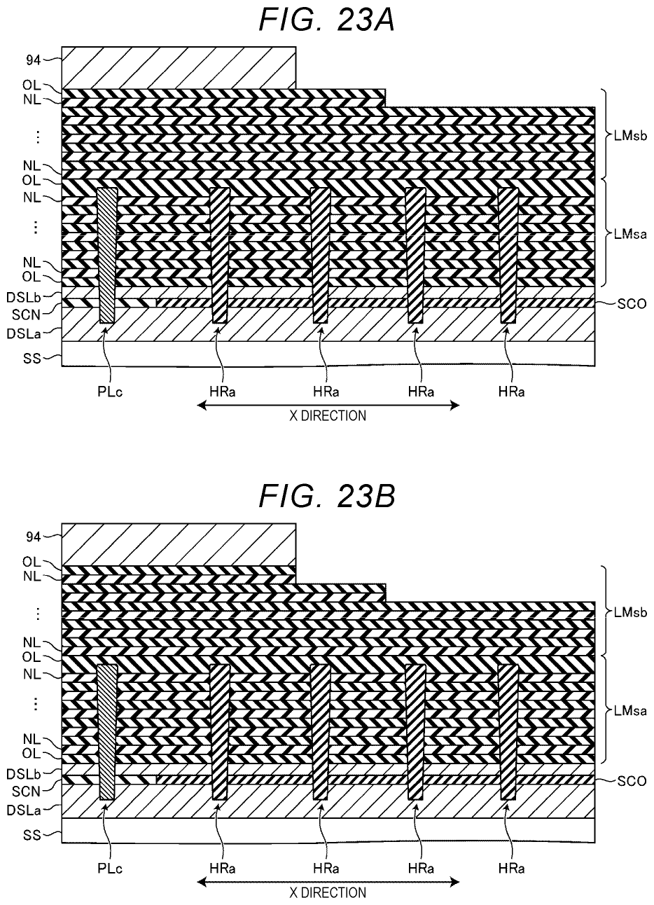

As shown in FIG. 23A, the end portion of the patterned resist 94 is retracted by a slimming processing using oxygen plasma or the like. As a result, the end portions of the pair of insulating layers NL and OL removed by the above-described processing are exposed.

As shown in FIG. 23B, for example, a pair of insulating layers NL and OL is removed from the upper surface of the stacked body LMsb newly exposed from the patterned resist 94. In addition, at this time, the pair of insulating layers NL and OL of the lower layer are further removed even in the region where the pair of insulating layers NL and OL are removed by the above-described processing. As a result, the uppermost insulating layers NL and OL and the second insulating layers NL and OL from the uppermost layer are processed in a stepped shape.

Even after that, the slimming of the patterned resist 94 and the removal of the insulating layers NL and OL are repeated in accordance with the number of layers of the select gate line SGD to be provided in the semiconductor memory device 1a later to process the insulating layers NL in a stepped shape by the number of layers of the select gate line SGD.

Thereafter, the patterned resist 94 is removed by ashing using oxygen plasma or the like.

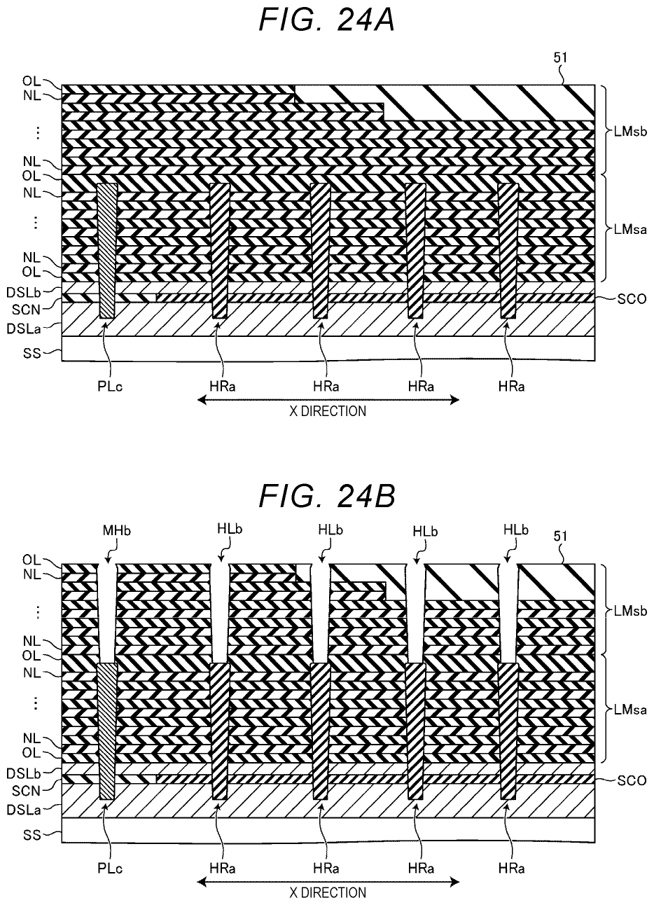

As shown in FIG. 24A, the insulating layer 51 that covers the upper surfaces of the insulating layers NL and OL processed in a stepped shape and reaches the height position of the upper surface of the unprocessed portion of the stacked body LMb is formed.

As shown in FIG. 24B, a memory hole MHb that penetrates the stacked body LMsb and reaches the pillar PLc is formed. In addition, the hole HLb that penetrates the insulating layer 51 and the stacked body LMsb and reaches the columnar portion HRa is formed. Thereafter, the pillar PL and the columnar portion HR are formed in the same manner as in the above-described Embodiment 1.

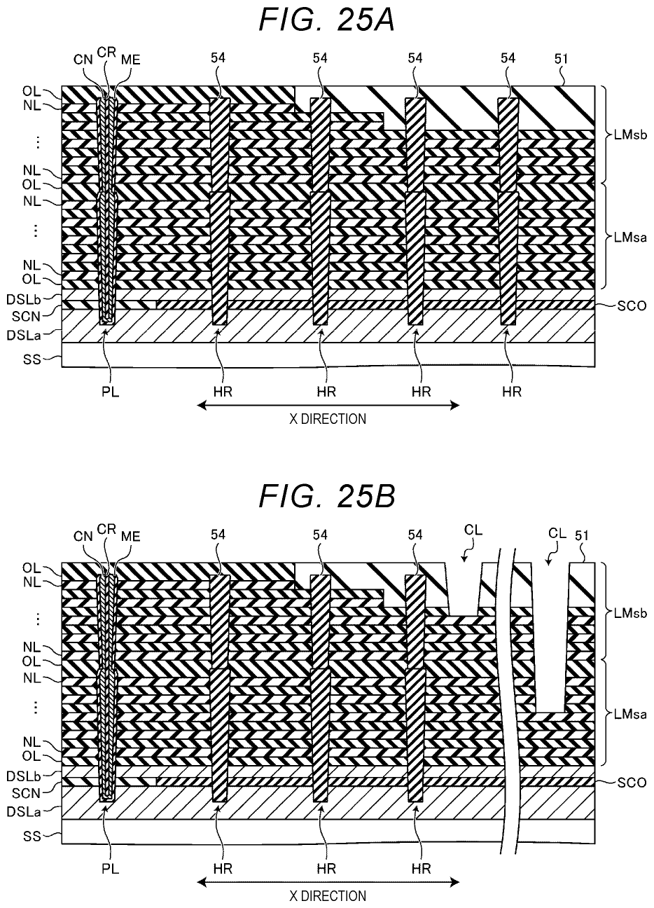

FIG. 25A shows a state in which the pillars PL and the columnar portion HR are formed. Meanwhile, at this stage, the intermediate source line BSL is not formed, and the channel layer CN is not exposed from the side surface of the pillar PL. That is, FIG. 25A corresponds to the state of FIG. 7B of Embodiment 1 described above.

As shown in FIG. 25B, a plurality of contact holes CL that penetrate the insulating layer 51 and the stacked body LM portion excluding the insulating layer NL that is processed into a stepped shape among the plurality of insulating layers NL and respectively reach the insulating layer NL of each layer disposed in the lower layer are formed. The contact hole CL is a portion to be the contact CC connected to the plurality of word lines WL and the select gate line SGS later.

Thereafter, as in FIG. 11 of Embodiment 1 described above, the insulating layer 56 is formed on the side walls and the lower surface of the contact hole CL, and the contact hole CL is filled with an insulating layer such as an amorphous silicon layer.

The contact hole CL as described above can be formed by the same method as in FIGS. 8A to 10C of Embodiment 1 described above. Meanwhile, at this stage, the contact hole to be the contact CCs connected to the select gate line SGD later is not formed.

While these contact holes are formed by penetrating the insulating layer 51, the above-described contact hole CL is formed by penetrating not only the insulating layer 51 but also the stacked structure of the insulating layers NL and OL. As described above, the contact hole to be the contact CCs later is formed by processing a layer structure different from the layer structure of the contact hole CL described above. Therefore, it is preferable that the contact hole to be the contact Ccs later is separately formed from the above-described contact hole CL, and thereby, all contact holes can be formed with high accuracy.

The contact hole to be the contact CCs later may be formed before or after the formation of the above-described contact hole CL. Meanwhile, as shown below, it is more convenient to form these contact holes after the replacement processing of the stacked body LM.

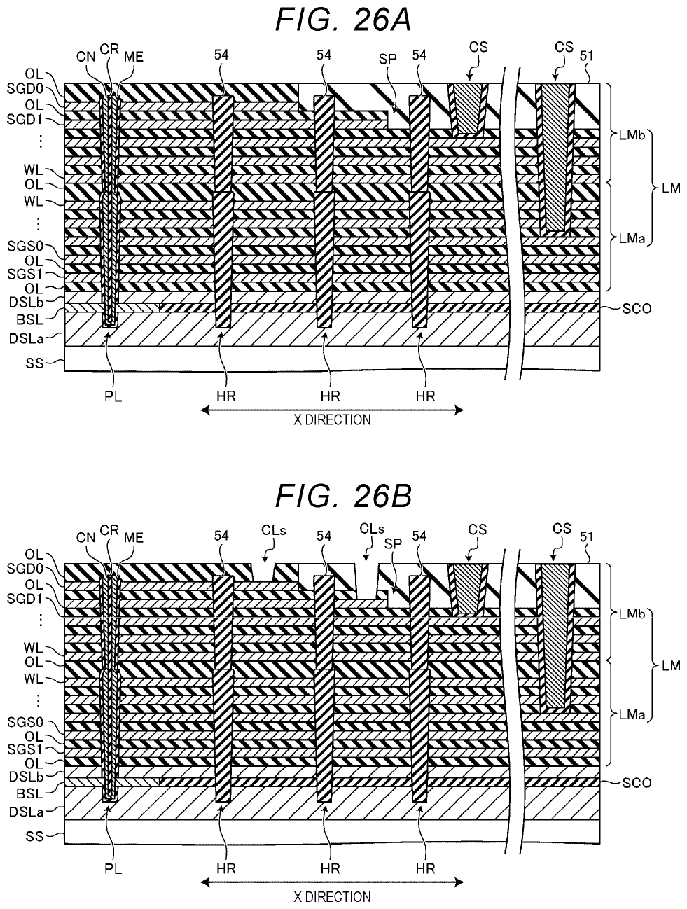

As shown in FIG. 26A, the intermediate sacrificial layer SCO is replaced with the intermediate source line BSL, and the channel layer CN of the pillar PL is connected. In addition, the insulating layers NL of the stacked bodies LMsa and LMsb are replaced with the word lines WL and the select gate lines SGD and SGS to form the stacked body LM. The separation layer SHEh may be formed until this point or may be formed thereafter.

As shown in FIG. 26B, a plurality of contact holes CLs that penetrate the insulating layer 51 and OL to respectively reach the select gate line SGD to be connected are formed.

In this way, the contact holes CLs can be collectively formed while considering a selection ratio to the formed select gate line SGD and the like, by forming the contact holes CLs after the replacement processing of the stacked body LM.

On the other hand, it is difficult to form the above-mentioned contact hole CL connected to the word line WL or the like of the lower layer by penetrating the plurality of word lines WL. Therefore, as described above, it is preferable to form the above-mentioned contact hole CL by penetrating the plurality of insulating layers NL before the replacement processing of the stacked body LM.

Thereafter, as in the above-described Embodiment 1, the insulating layer 56 is formed on the side wall of the contact hole CLs and CL, and the inside is filled with the conductive layer 26 to form a plurality of contacts CCs and CC. Meanwhile, the insulating layer 56 may not be provided on the side wall of the contact CCs that penetrates only the insulating layer 51.

In addition, the plugs CH and V0, the bit line BL, the upper-layer wiring MX, and the like are formed, and, for example, bonding to the semiconductor substrate SB on which the peripheral circuit CBA is formed is performed.

As described above, the semiconductor memory device 1a of Modification Example 1 is manufactured.

According to the semiconductor memory device 1a of Modification Example 1, the stacked body LM has the stepped part SP in which the select gate line SGD is processed in a stepped shape in which the height position of the terrace surface is lowered from the contact CCs side toward the contact CC side. In addition, the contacts CCs are connected to each of the select gate lines SGD and the terrace surface.

Accordingly, for example, the plurality of contact CCs can be collectively formed without adopting the method of FIGS. 8A to 10C described above. Therefore, it is possible to more easily form the plurality of contacts CCs.

In addition, the method of Modification Example 1, in which the select gate line SGD is configured in a stepped shape and the contact CCs are connected to the terrace surfaces, is also considered to be inefficient as compared with the method of Embodiment 1 described above, in which the contact CCs penetrating the stacked body LM are connected to the select gate line SGD to be connected. However, also in Modification Example 1, since the diameter of the contact CCs is smaller than that of the contact CC, the design of the separation layer SHEh and the arrangement of the contact CCs can be made simple. Therefore, the merit of the area reduction of the contact region ERda is higher, and a sufficient effect can be obtained even in the configuration of Modification Example 1.

According to the semiconductor memory device 1a of Modification Example 1, the contact CC penetrates the word line WL lower than the select gate line SGD and reaches the depth position of the word line WL or the select gate line SGS to be connected among the plurality of word lines WL or select gate lines SGS.

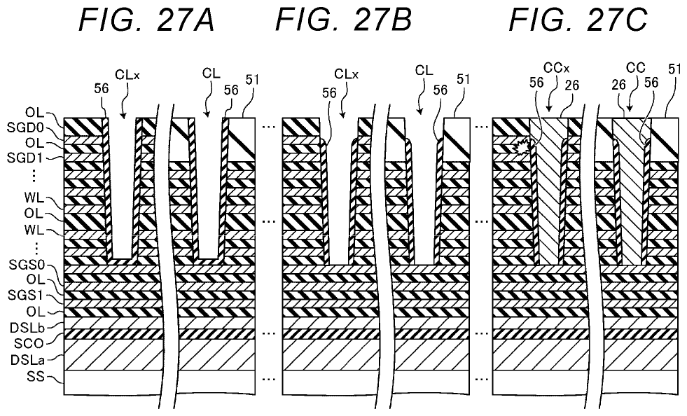

As described above, the select gate line SGD is not disposed in the vicinity of the upper end portion of the contact CC, and the contact CC penetrates the lower layer word line WL and the like and extends in the stacked body LM. Accordingly, it is possible to prevent a short circuit between the contact CC and the select gate line SGD. This point will be described below with reference to FIGS. 27A to 27C.

FIGS. 27A to 27C are cross-sectional views showing a state in which contacts CC and CCx are formed in the semiconductor memory device according to Modification Example 1 of Embodiment 1 and the comparative example. The left sides of the drawings of FIGS. 27A to 27C show a state in which the contact CCx of the comparative example is formed, and the right sides of the drawings show a state in which the contact CC of Modification Example 1 is formed.

As shown in FIG. 27A, after the sacrificial layer such as the amorphous silicon layer is removed, the insulating layer 56 is formed on each of the side wall and the lower surface of the contact hole CLx of the comparative example and the contact hole CL of Modification Example 1.

As shown in FIG. 27B, the insulating layer 56 is removed from the lower surfaces of the contact holes CLx and CL. At this time, even the insulating layer 56 on the upper end portion side surface of the contact holes CLx and CL may be removed.

As shown in FIG. 27C, the contact holes CLx and CL are filled with the conductive layer 26 through the insulating layer 56 of the side wall to form the contact CCx of the comparative example and the contact CC of Modification Example 1.

Meanwhile, as described above, when the insulating layer 56 on the upper end portion side surface of the contact hole CLx is removed, the select gate line SGD or the like of the stacked body LM upper layer is exposed in the contact hole CLx. As a result, the conductive layer 26 provided in the contact hole CLx and the select gate line SGD exposed in the contact hole CLx may be short-circuited.

On the other hand, in Modification Example 1, even when the insulating layer 56 at the upper end portion of the contact hole CL is removed, the insulating layer 51 covering the height position of the select gate line SGD processed in a stepped shape is exposed in the contact hole CLx. Accordingly, it is possible to prevent a short circuit between the conductive layer 26 filled with the contact hole CL and the select gate line SGD or the like.

According to the semiconductor memory device 1a of Modification Example 1, the same effects as those of the semiconductor memory device 1 of the above-described Embodiment 1 are obtained.

### Modification Example 2

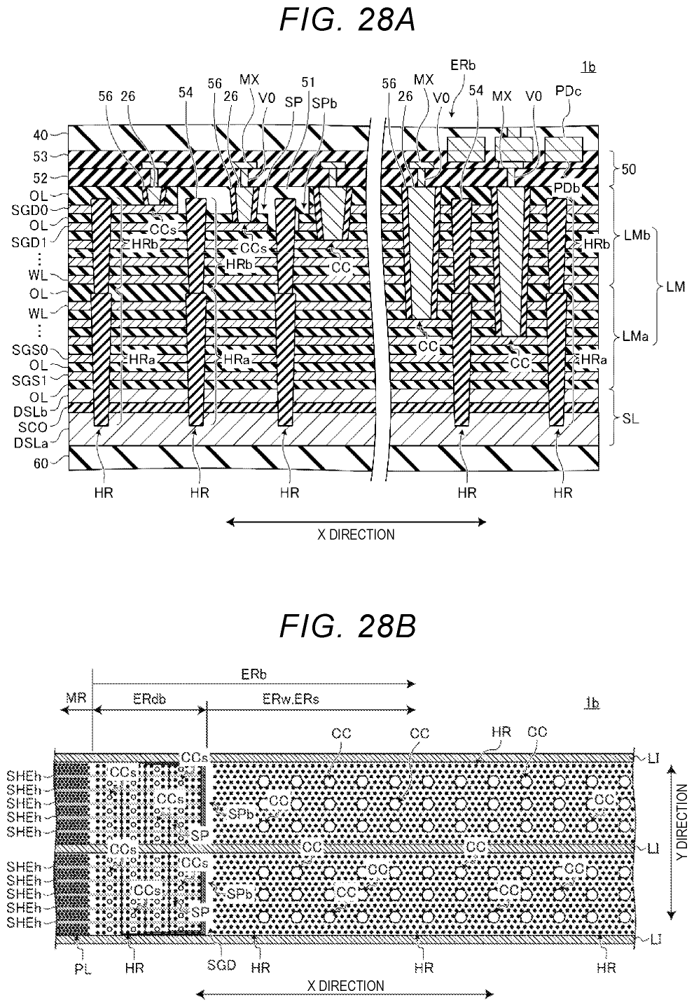

Next, a semiconductor memory device 1b of Modification Example 2 of Embodiment 1 will be described with reference to FIGS. 28A to 30B. The semiconductor memory device 1b of Modification Example 2 is different from that of Embodiment 1 described above in that the select gate line SGD is processed in a stepped shape on both the contact CCs and CC sides.

In the following drawings, the same reference numerals are given to the same configurations as in Embodiment 1, and the description thereof may be omitted.

FIGS. 28A and 28B are diagrams showing an example of a configuration of a semiconductor memory device 1b according to Modification Example 2 of Embodiment 1. More specifically, FIG. 28A is a cross-sectional view taken along the X direction showing an example of the configuration of the contact region ERb. FIG. 28B is an XY cross-sectional view including the contact region ERb at the height position of the select gate line SGD.

Meanwhile, in FIG. 28A, the structure below the insulating layer 60 and the structure above the insulating layer 40 are not shown. In addition, the number, the arrangement, and the like of each configuration in the cross-sectional view in the Y direction of FIG. 28A and those in the XY cross-sectional view in FIG. 28B do not necessarily match.

As shown in FIG. 28, the semiconductor memory device 1b is provided with a stepped part SPb as a second stepped part in which the select gate line SGD of the stacked body LMb is processed in a stepped shape, in addition to the stepped part SP of Modification Example 1 described above.

The stepped part SPb is disposed at a position facing the stepped part SP in the X direction, and has a shape in which the select gate line SGD is processed in a stepped shape in which the height position of the terrace surface is lowered as the select gate line SGD approaches the memory region MR. In addition, for example, the terrace surface of the stepped part SPb is narrower than the terrace surface of the stepped part SP, and thus, the stepped part SPb has an inclination steeper than that of the stepped part SP and has a stage length shorter than that of the stepped part SP. The stage length is the distance from the uppermost stage to the lowermost stage.

The contact Ccs and Cc, and the like are not disposed in the stepped part SPb having the narrow terrace surface in this way, and the stepped part SPb is a dummy stepped part having no function of drawing the select gate line SGD to the upper-layer wiring MX and the like.

The plurality of contacts CC respectively connected to the plurality of word lines WL and the select gate line SGS are disposed at positions separated from the contacts CCs by the stepped parts SP and SPb. Since the select gate line SGD that is once interrupted between the stepped parts SP and SPb is disposed again at the arrangement position of the contacts CC, these contacts CC penetrate the stacked body LM provided with the select gate line SGD and are connected to the word line WL or the select gate line SGS to be connected.

In addition, also in the configuration of Modification Example 2, the select gate line SGD is once interrupted between the stepped parts SP and SPb, the select gate line SGD does not have electrical conduction with the contact CCs side and the contact CC side, and the separation layer SHEv extending in the direction along the Y direction is not disposed between the contacts CCs and CC.

As described above, the contact region ERb of Modification Example 2 has the contact region ERdb having the stepped parts SP and SPb in which the select gate line SGD is processed in a stepped shape and the contact regions ERw and ERs in which the select gate line SGD is the uppermost layer, as in Embodiment 1 described above.

Among these contact regions ERda, ERwa, and ERsa, the contact region ERdb is covered with the insulating layer 51 that reaches the height position of the upper surface of the unprocessed portion of the stacked body LMb. That is, the insulating layer 51 covers the stepped parts SP and SPb of the contact region ERdb.

In Modification Example 2, the insulating layer 56 may not be provided on the side walls of the plurality of contacts CCs extending in the insulating layer 51.

The semiconductor memory device 1b of Modification Example 2 as described above can be manufactured as follows.

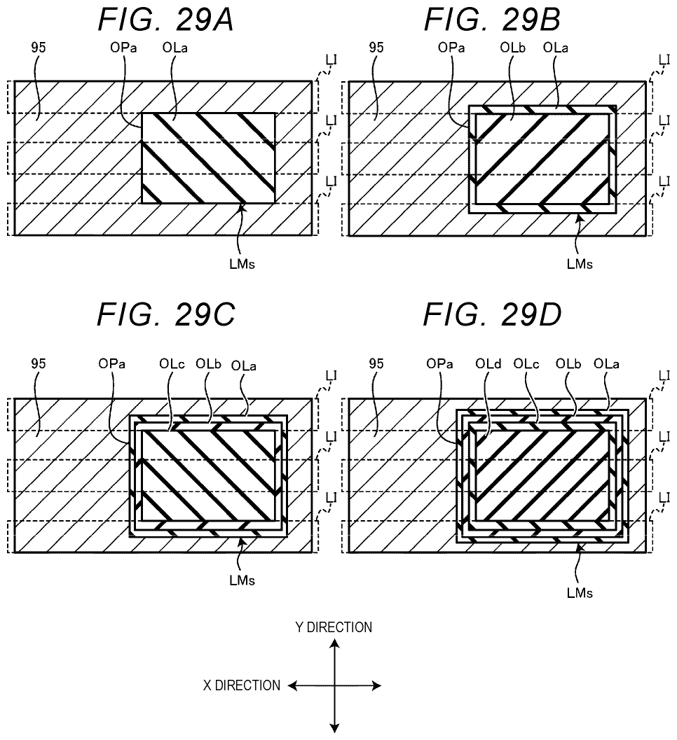

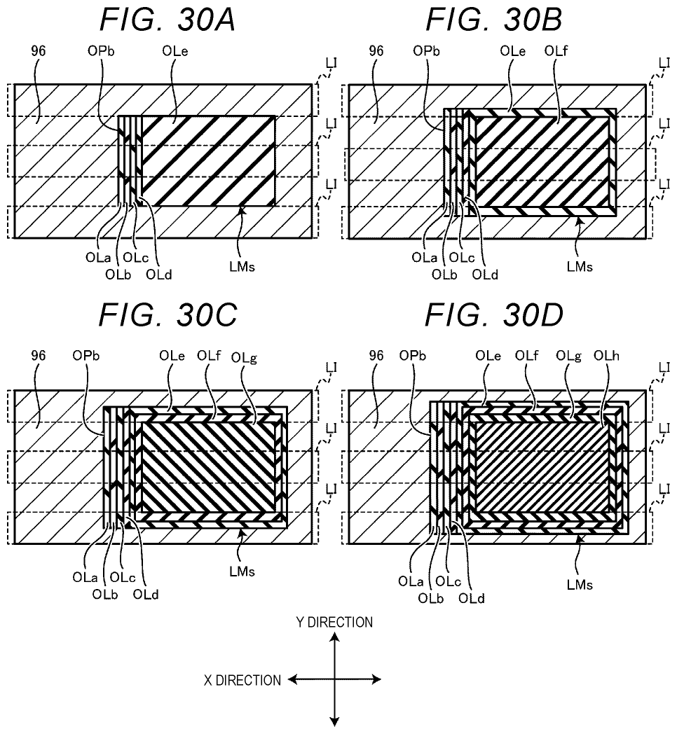

FIGS. 29A to 30D are diagrams sequentially illustrating some procedures of the manufacturing method of the semiconductor memory device 2a according to Modification Example 2 of Embodiment 1. More specifically, FIGS. 29A and 30D are top views showing how the stepped parts SP and SPb of the semiconductor memory device 2a are formed.

As shown in FIG. 29A, for example, a patterned resist 95 having a rectangular opening OPa is formed on the upper surface of the stacked body LMs. At this time, the opening OPa of the patterned resist 95 is formed in the region in which the stepped parts SP and SPb straddle the portion, in which the plate-shaped contact LI is formed later, in the Y direction. In addition, the end portions of the opening OPa facing each other in the X direction are respectively disposed at the lowermost stages of stepped parts SP and SPb, and the end portions of the opening OPa facing each other in the Y direction are disposed at positions in which the plate-shaped contacts LI adjacent to the plate-shaped contacts LI formed in the center of the opening OPa on both sides in the Y direction are formed.

In addition, for example, the pair of insulating layers OL and NL (refer to FIGS. 22A and 22B and the like) are removed from the upper surface of the stacked body LMs exposed from the opening OPa of the patterned resist 95. As a result, the second insulating layer OLa from the uppermost layer of the stacked body LMs is exposed from the opening OPa of the patterned resist 95.

As shown in FIG. 29B, the opening Opa of the patterned resist 95 is enlarged by slimming using oxygen plasma or the like. As a result, the unprocessed upper surface of the stacked body LM is newly exposed around the second insulating layer OLa from the uppermost layer of the stacked body LMs.

In addition, for example, the pair of insulating layers OL and NL are removed from the upper surface of the stacked body LMs exposed from the opening OPa of the patterned resist 95. As a result, the pair of insulating layers OL and NL provided with the insulating layer OLa previously exposed in the center of the opening OPa of the patterned resist 95 is removed, and the third insulating layer OLb from the uppermost layer of the stacked body LMs is exposed. In addition, the insulating layer OLa is newly exposed so as to surround the periphery of the insulating layer OLb.

As shown in FIG. 29C, the opening OPa of the patterned resist 95 is enlarged by slimming using oxygen plasma or the like. As a result, the unprocessed upper surface of the stacked body LM is newly exposed around the second insulating layer OLa from the uppermost layer of the stacked body LMs.

In addition, for example, the pair of insulating layers OL and NL are removed from the upper surface of the stacked body LMs exposed from the opening OPa of the patterned resist 95. As a result, the pair of insulating layers OL and NL provided with the insulating layer OLb previously exposed in the center of the opening OPa of the patterned resist 95 is removed, and the third insulating layer OLc from the uppermost layer of the stacked body LM is exposed. In addition, the insulating layer OLb is newly exposed so as to surround the periphery of the insulating layer OLc. Further, the insulating layer OLa is newly exposed so as to surround the periphery of the insulating layer OLb.

As shown in FIG. 29D, the opening Opa of the patterned resist 95 is enlarged by slimming using oxygen plasma or the like. As a result, the unprocessed upper surface of the stacked body LM is newly exposed around the second insulating layer OLa from the uppermost layer of the stacked body LMs.

In addition, for example, the pair of insulating layers OL and NL are removed from the upper surface of the stacked body LMs exposed from the opening OPa of the patterned resist 95. As a result, the pair of insulating layers OL and NL provided with the insulating layer OLc previously exposed in the center of the opening OPa of the patterned resist 95 is removed, and the fourth insulating layer OLd from the uppermost layer of the stacked body LMs is exposed.

In addition, the insulating layer OLc is newly exposed so as to surround the periphery of the insulating layer OLd, the insulating layer OLb is newly exposed so as to surround the periphery of the insulating layer OLc, and the insulating layer OLa is newly exposed so as to surround the periphery of the insulating layer OLb.

As described above, the slimming of the patterned resist 95 and the removal of the insulating layers OL and NL are repeated a plurality of times, whereby the insulating layers OLc to OLa, which have the insulating layer OLd of the center of the opening OPa as the lower surface and are processed in a stepped shape around the insulating layer OLd, are formed.

On the other hand, the patterned resist 95 has a layer thickness less than a desired layer thickness by repeating the slimming. Therefore, after the above-described processing is repeated a predetermined number of times, the patterned resist 95 is once removed by ashing using oxygen plasma or the like.

As shown in FIG. 30A, for example, a patterned resist 96 having a rectangular opening OPb is newly formed. At this time, the opening OPb of the patterned resist 96 is disposed so as to substantially overlap the position in which the opening OPa of the patterned resist 95 before slimming is disposed. One end portion of the opening OPb facing the X direction is disposed at a position slightly retreated from the end portion of the insulating layer OLa newly exposed in the processing of FIG. 29D.

Accordingly, the insulating layers OLc to OLa, which has the insulating layer OLd as the lower surface and is processed in a stepped shape on one side in the X direction of the insulating layer OLd, and the unprocessed upper surface of the stacked body LMs are exposed from the opening OPb of the patterned resist 96. In addition, the stepped insulating layers OLc to OLa formed on the other side of the insulating layer OLd in the X direction and on both sides in the Y direction are in a state of being covered with the patterned resist 96.

In addition, for example, the pair of insulating layers OL and NL are removed from the upper surface of the stacked body LMs exposed from the opening OPb of the patterned resist 96. As a result, the pair of insulating layers OL and NL provided with the insulating layer OLd previously exposed is removed, and the fifth insulating layer OLe from the uppermost layer of the stacked body LMs is exposed on the lower surface of the opening OPb of the patterned resist 96.

In addition, the insulating layers OL and NL provided with the insulating layers OLc to OLa and the insulating layer OL on the upper surface of the stacked body LMs are removed from the region on one side in the X direction of the insulating layer OLe, and the stepped insulating layers OLd to OLa are newly exposed.

As shown in FIG. 30B, the opening OPb of the patterned resist 96 is enlarged by slimming using oxygen plasma or the like. As a result, the insulating layers OLd to OLa processed in a stepped shape on one side in the X direction of the insulating layer OLe serving as the lower surface, and the unprocessed upper surface of the stacked body LMs are exposed. In addition, a part of the stepped insulating layers OLc to OLa formed on the other side of the insulating layer OLe in the X direction and on both sides in the Y direction is exposed.

In addition, for example, the pair of insulating layers OL and NL are removed from the upper surface of the stacked body LMs exposed from the opening OPb of the patterned resist 96. As a result, the pair of insulating layers OL and NL provided with the insulating layer OLe previously exposed is removed, and the sixth insulating layer OLf from the uppermost layer of the stacked body LMs is exposed on the lower surface of the opening OPb of the patterned resist 96.

In addition, the insulating layers OL and NL provided with the insulating layers OLd to OLa and the insulating layer OL on the upper surface of the stacked body LMs are removed from the region of one side in the X direction of the insulating layer OLf, and the stepped insulating layers OLe to OLa are newly exposed. In addition, a part of the insulating layers OLc to OLa exposed on the other side of the insulating layer OLf in the X direction and on both sides in the Y direction is removed.

As shown in FIG. 30C, the opening OPb of the patterned resist 96 is enlarged by slimming using oxygen plasma or the like. As a result, the insulating layers OLe to OLa processed in a stepped shape on one side in the X direction of the insulating layer OLf serving as the lower surface, and the unprocessed upper surfaces of the stacked body LMs are exposed. In addition, another part of the stepped insulating layers OLc to OLa formed on the other side of the insulating layer OLf in the X direction and on both sides in the Y direction is exposed.

In addition, for example, the pair of insulating layers OL and NL are removed from the upper surface of the stacked body LMs exposed from the opening OPb of the patterned resist 96. As a result, the pair of insulating layers OL and NL provided with the insulating layer OLf previously exposed is removed, and the seventh insulating layer OLg from the uppermost layer of the stacked body LMs is exposed on the lower surface of the opening OPb of the patterned resist 96.

In addition, the insulating layers OL and NL provided with the insulating layers OLe to OLa and the insulating layer OL on the upper surface of the stacked body LMs are removed from the region of one side in the X direction of the insulating layer OLg, and the stepped insulating layers OLf to OLa are newly exposed. In addition, another part of the insulating layers OLc to OLa exposed on the other side of the insulating layer OLg in the X direction and on both sides in the Y direction is removed.

As shown in FIG. 30D, the opening OPb of the patterned resist 96 is enlarged by slimming using oxygen plasma or the like. As a result, the insulating layers OLf to OLa processed in a stepped shape on one side in the X direction of the insulating layer OLg serving as the lower surface, and the unprocessed upper surfaces of the stacked body LMs are exposed. In addition, another part of the stepped insulating layers OLc to OLa formed on the other side of the insulating layer OLg in the X direction and on both sides in the Y direction is exposed.

In addition, for example, the pair of insulating layers OL and NL are removed from the upper surface of the stacked body LMs exposed from the opening OPb of the patterned resist 96. As a result, the pair of insulating layers OL and NL provided with the insulating layer OLg previously exposed is removed, and the eighth insulating layer OLh from the uppermost layer of the stacked body LMs is exposed on the lower surface of the opening OPb of the patterned resist 96.

In addition, the insulating layers OLf to OLa and the insulating layers OL and NL provided with the insulating layer OL on the upper surface of the stacked body LMs are removed from the region on one side in the X direction of the insulating layer OLh, and the stepped insulating layers OLg to OLa are newly exposed. In addition, another part of the insulating layers OLc to OLa exposed on the other side of the insulating layer OLg in the X direction and on both sides in the Y direction is removed.

As described above, the slimming of the patterned resist 96 and the removal of the insulating layers OL and NL are repeated a plurality of times, whereby a configuration corresponding to the above-described stepped part SP in which the insulating layers OLg to OLa are processed in a stepped shape is formed on one side of the insulating layer OLh of the lower surface of the opening OPb in the X direction.

In addition, a configuration corresponding to the above-described stepped part SPb having a terrace surface narrower than that of the stepped part SP and a steep inclination is formed by performing processing of repeatedly removing the insulating layers OL and NL from the insulating layers OLc to OLa on the other side in the X direction of the insulating layer OLh and on both sides in the Y direction. That is, in the methods shown in FIGS. 29A and 30D, a configuration corresponding to the stepped part SPb is formed not only at a position facing the configuration corresponding to the stepped part SP in the X direction, but also on both sides of the contact region ERdb in the Y direction, for example.

Thereafter, the plate-shaped contact LI is formed at a position overlapping the stepped part SPb on both sides in the Y direction, so that the electrical conduction between the select gate line SGD on the contact region ERdb side to which the plurality of contacts CCs are connected and the select gate line SGD on the contact region ERw side in which the plurality of contacts CC are disposed is cut off.

In addition, hereinafter, the contact CCs extending in the insulating layer 51 and the contact CC extending in the stacked body LM are formed separately as in Modification Example 1 described above. In addition, the subsequent processing is performed in the same manner as in Embodiment 1 and Modification Example 1 described above.

As described above, the semiconductor memory device 1b of Modification Example 2 is manufactured.

According to the semiconductor memory device 1b of Modification Example 2, the plurality of contacts CC penetrate the plurality of word lines WL at a position separated in the X direction from the contact CCs across the stepped part SPb and reach the depth position of the word line WL or the select gate line SGS to be connected among the plurality of word lines WL and the select gate lines SGS.

Accordingly, when the contact hole to be the contact CC later is formed, the contact hole is formed by penetrating the stacked structure of the insulating layers OL and NL in a consistent manner. Therefore, it is possible to reduce the influence of the difference in the layer configuration at the time of forming the contact hole.

The above points also have the same effect when a hole to be the columnar portion HRb later is formed. That is, for example, when the hole to be the columnar portion HRb later and the memory hole to be the pillar PLb later are formed together, it is possible to reduce the influence of the difference in the layer configuration at the time of forming the hole and the memory hole.

According to the semiconductor memory device 1b of Modification Example 2, the stepped part SPb is a dummy stepped part having an inclination steeper than that of the stepped part SP and to which none of the contacts CCs and CC is connected. By configuring the stepped part SPb in this way, it is possible to reduce an increase in the area of the contact region ERdb.

According to the semiconductor memory device 1b of Modification Example 2, the same effects as those of the semiconductor memory device 1 of the above-described Modification Example 1 of Embodiment 1 are obtained.

### Embodiment 2

Hereinafter, Embodiment 2 will be described in detail with reference to the drawings. The semiconductor memory device of Embodiment 2 is different from the above-described Embodiment 1 in that the semiconductor memory device of Embodiment 2 is provided with a plurality of select gate lines electrically connected to each other.

In the following drawings, the same reference numerals are given to the same configurations as in Embodiment 1, and the description thereof may be omitted.

### Configuration Example of Semiconductor Memory Device

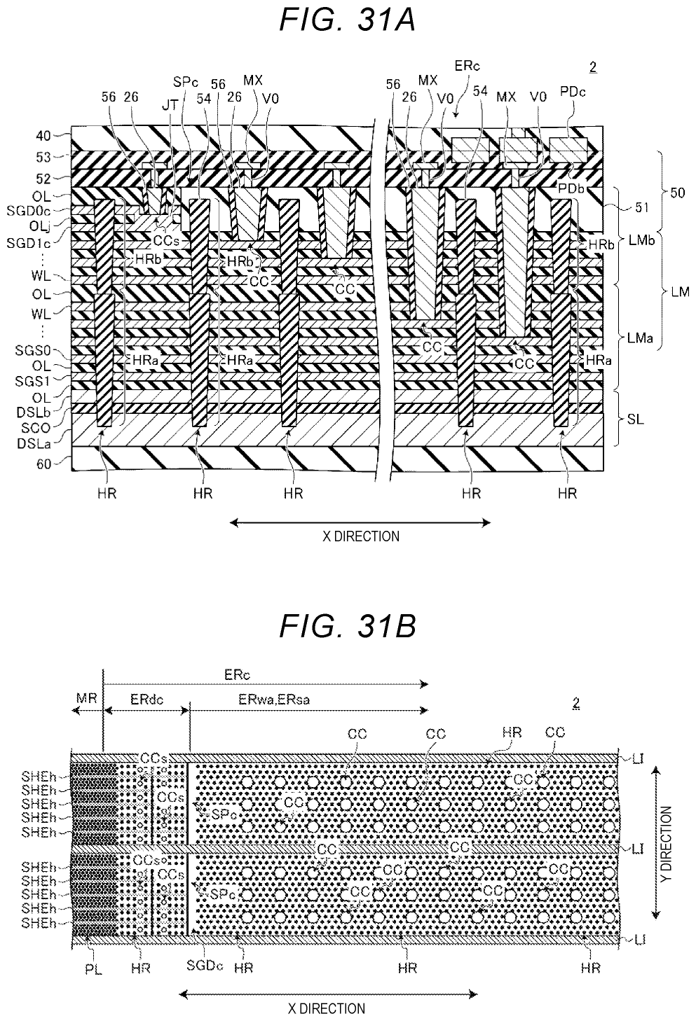

FIGS. 31A and 31B are diagrams showing an example of a configuration of the semiconductor memory device 2 according to Embodiment 2. More specifically, FIG. 31A is a cross-sectional view taken along the X direction showing an example of the configuration of the contact region ERc. FIG. 31B is an XY cross-sectional view provided with the contact region ERc at the height position of the select gate line SGDc.

In FIG. 31A, the structure below the insulating layer 60 and the structure above the insulating layer 40 are not shown. In addition, the number, the arrangement, and the like of each configuration in the cross-sectional view in the Y direction of FIG. 31A and those in the XY cross-sectional view of FIG. 31B do not necessarily match.

As shown in FIG. 31, the semiconductor memory device 2 of Embodiment 2 is provided with a contact region ERdc having a stepped part SPc in which the plurality of select gate lines SGDC are processed in a stepped shape, and a contact region Erc including the contact regions Erwa and Ersa that have the insulating layer OL immediately above the uppermost word line WL among the plurality of word lines WL as the uppermost layer of the stacked body LMb, as in Modification Example 1 of Embodiment 1 described above.

These contact regions Erdc, Erwa, and Ersa are covered with the insulating layer 51 that reaches the height position of the upper surface of the unprocessed portion of the stacked body LMb, as in Modification Example 1 of Embodiment 1 described above. The above-mentioned insulating layers 52 and 53 covering the upper surface of the stacked body LM also cover the upper surface of the insulating layer 51.

Meanwhile, in the semiconductor memory device 2 of Embodiment 2, the plurality of select gate lines SGD0c and SGD1c are electrically connected to each other through the insulating layer Olj interposed therebetween. More specifically, a part of the insulating layer Olj interposed between the select gate lines SGD0c and SGD1c penetrates, and a connection portion JT to which the select gate lines SGD0c and SGD1c are in contact is provided in the penetrating portion of the insulating layer Olj.

In addition, in the stepped part SPc, the select gate lines SGD0c and SGD1c and the insulating layers OL and Olj immediately above the select gate lines SGD0c and SGD1c are processed in a stepped shape with one stage. The contact CCs are connected to the uppermost select gate line SGD0c among the select gate lines SGD0c and SGD1c electrically connected to each other on the terrace surface of the stepped part SPc. That is, the plurality of select gate lines SGD0c and SGD1c electrically connected to each other share one contact CCs.

The contact CCs are preferably disposed on, for example, the connection portion JT of the select gate lines SGD0c and SGD1c as in the example of FIG. 31A. Accordingly, when a voltage is applied via the contact CCs, the voltage can be quickly applied to both of the select gate lines SGD0c and SGD1c. Meanwhile, the contact CCs may be connected to the select gate line SGD0c at a position away from the connection portion JT.

FIG. 31B shows an example in which the stacked body LM is provided with four select gate lines SGD, and the two upper layers of the select gate lines SGD are connected to each other and the two lower layers of the select gate lines SGD are connected to each other.

Therefore, in the example of FIG. 31B, the stepped part SPc is processed in a two-stage stepped shape by the two upper layers of select gate lines SGD and the two lower layers of select gate lines SGD. In addition, in each region of the select gate line SGD that is separated into six regions by the separation layer SHEh, one contact CCs is connected to the upper side and one contact CCs is connected to the lower side.

As described above, the plurality of layers of the select gate lines SGD have a function of turning on or off the plurality of select gates STD corresponding to the plurality of layers of the select gate lines SGD to set the memory cell MC of the pillar PL to which these select gates STD belong to a selected state or a non-selected state. Therefore, the same voltage is applied to the plurality of layers of the select gate lines SGD at the same timing, and the plurality of select gate lines STD corresponding to the plurality of select gate lines SGD perform the on/off operation at the same timing.

Therefore, the semiconductor memory device 2 of Embodiment 2 can electrically connect these plurality of layers of the select gate lines SGD as described above and collectively supply the voltage from the common contact CCs. As a result, the select gates STD corresponding to these are collectively controlled.

In this way, the plurality of select gate lines SGD are electrically connected, and the contacts CCs are shared between these select gate lines SGD, so that the number of stages of the stepped part SPc and the number of contacts CCs disposed in the stepped part SPc are reduced, and the area of the contact region Erdc is further reduced.

### Manufacturing Method of Semiconductor Memory Device

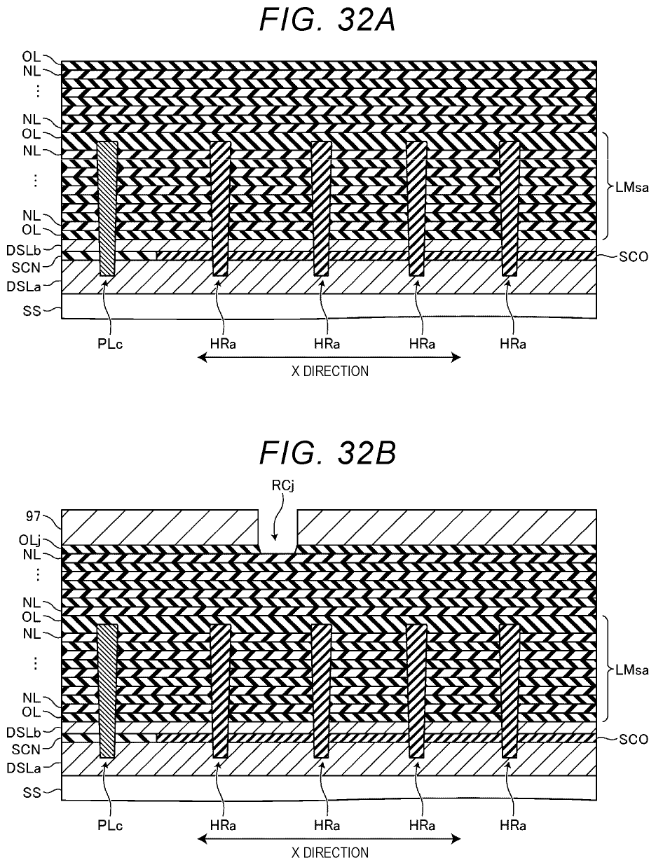

Next, a manufacturing method of the semiconductor memory device 2 according to Embodiment 2 will be described with reference to FIGS. 32A to 37B. FIGS. 32A to 37B are diagrams sequentially illustrating some procedures of the manufacturing method of the semiconductor memory device 2 according to Embodiment 2.

More specifically, FIGS. 32A to 37B show cross sections of the semiconductor memory device 2 under manufacturing along the X direction, including a region to be the memory region MR later and a region to be the contact region Erc later.

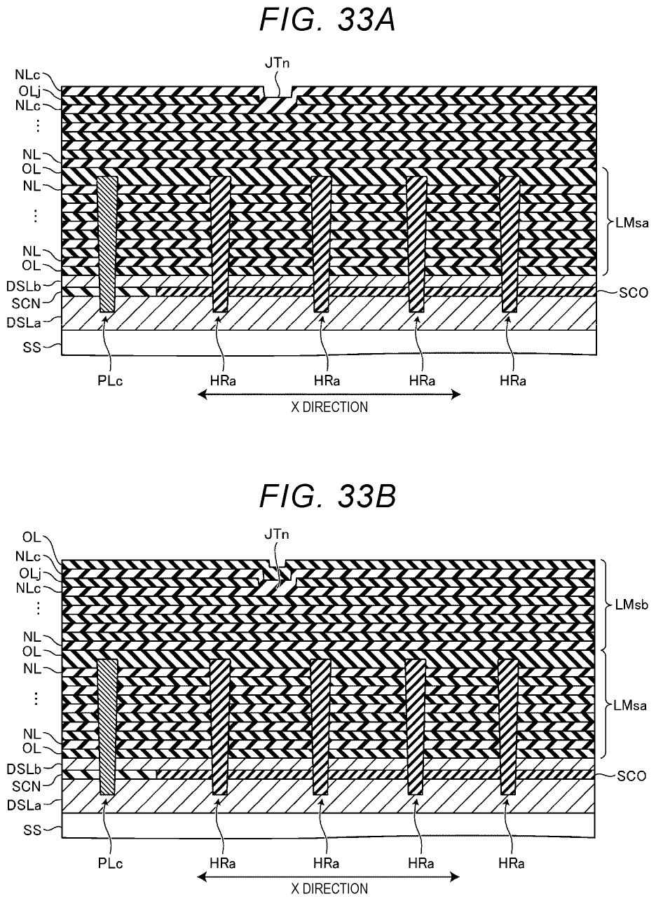

In the semiconductor memory device 2 of Embodiment 2, the same processing as the processing shown in FIGS. 4A to 4C of Embodiment 1 described above is performed. FIGS. 32A to 33B show a state in which the stacked body LMsb is formed after the processing of FIG. 4.

As shown in FIG. 32A, a plurality of insulating layers OL and NL are alternately stacked on the stacked body Lmsa on which the pillar PLc and the columnar portion Hra are formed, one layer at a time. The above-described processing is continued up to the insulating layer NL of the lowermost layer and the insulating layer OL immediately above the insulating layer NL among the insulating layers NL to be replaced with the conductive layer to form the select gate line SGD.

As shown in FIG. 32B, a patterned resist 97 having an opening in a part is formed on the upper surface of the uppermost insulating layer OL. In addition, a recess RCj that penetrates the uppermost insulating layer OL exposed from the opening is formed via the patterned resist 97. As a result, the insulating layer Olj having the recess RCj is formed on the uppermost layer.

Thereafter, the patterned resist 97 is removed by ashing using oxygen plasma or the like.

As shown in FIG. 33A, the insulating layer NL is formed on the insulating layer Olj in which the recess RCj is formed. Accordingly, the insulating layer NL is formed also in the recess RCj of the insulating layer Olj and is connected to the insulating layer NL of the lower layer exposed in the recess RCj. That is, the recess portion RCj of the insulating layer Olj serves as a penetrating portion, and a connection portion JTn that connects two insulating layers NLc stacked up and down via the insulating layer Olj is formed.

As shown in FIG. 33B, the insulating layer OL is further formed on the insulating layer NL connected to the lower insulating layer NL at the connection portion JTn.

When the insulating layer NL to be the select gate line SGD later is further formed on the upper layer, the recess RCj can be formed in the insulating layer OL in which the insulating layers NL to be connected are disposed up and down, and the processing of stacking the insulating layers NL and OL thereon can be repeated.

At this time, the insulating layers NL arranged in the stacking direction can be connected in units of two or three layers according to the number of layers of the select gate line SGD provided in the semiconductor memory device 2. By reducing the number of insulating layers NL connected to each other to about two or three layers, it is possible to reduce a decrease in the reaction rate of the select gate line SGD when a voltage is applied via the contact CCs.

The subsequent processing can be performed in the same manner as, for example, Modification Example 1 of Embodiment 1 described above.

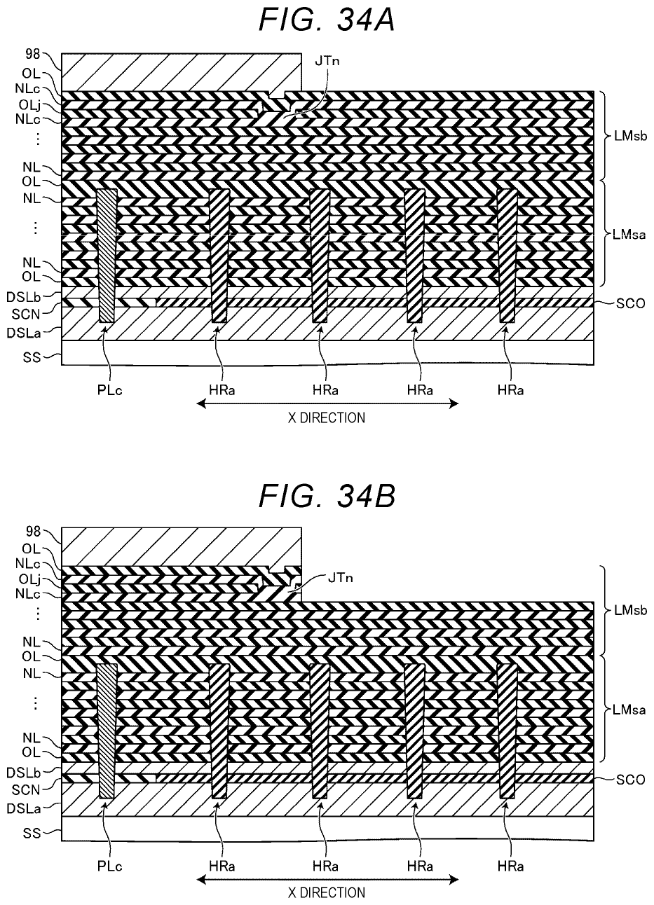

That is, as shown in FIG. 34A, a patterned resist 98 that covers a part of the upper surface of the stacked body LMsb is formed, and as shown in FIG. 34B, the insulating layers OL and NL are removed from the upper surface of the stacked body LMsb exposed from the patterned resist 98. At this time, a plurality of the insulating layers NLc connected to each other by the connection portion JTn and the insulating layers OL opposite to the insulating layers NLc are collectively removed.

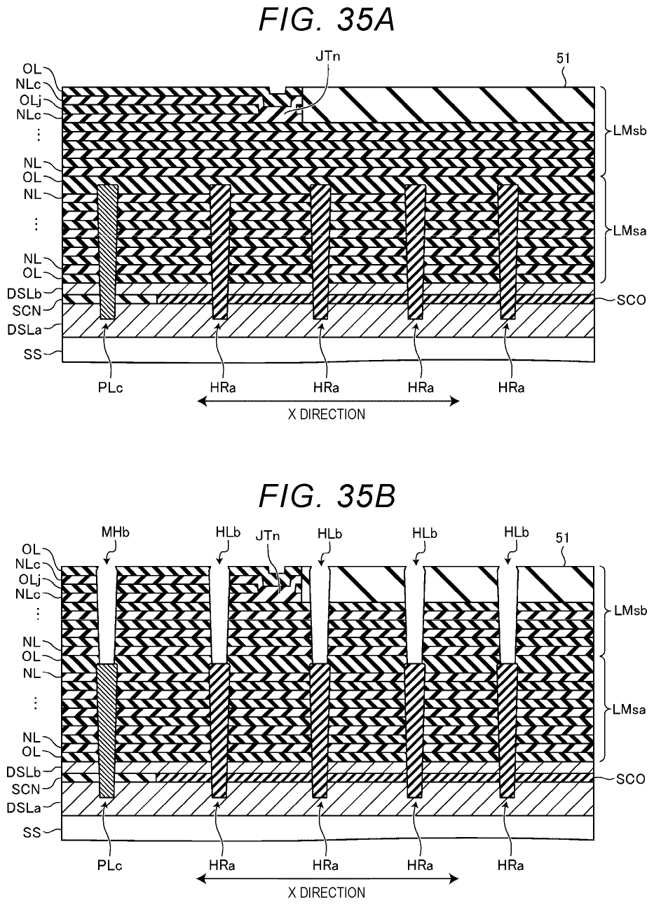

As shown in FIG. 35A, the plurality of insulating layers NLc processed in a stepped shape and the upper surfaces of the insulating layers OL lower than the insulating layers NLc exposed on the upper surface of the stacked body LMsb are covered with the insulating layer 51, and as shown in FIG. 35B, a plurality of memory holes MHb and holes HLb reaching the pillar PLc and the columnar portion Hra, respectively, are formed in the stacked body LMsb.

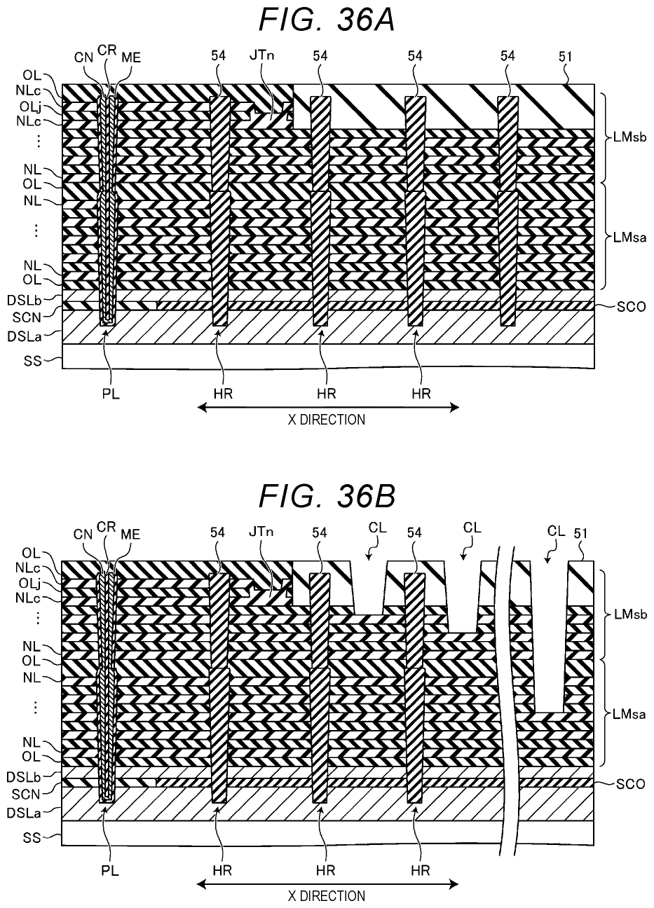

As shown in FIG. 36A, the pillar PL and the columnar portion HR are formed as in Embodiment 1 described above, and as shown in FIG. 36B, a plurality of contact holes CL serving as the contact CC to be connected to the word line WL and the like are formed by the same method as in FIGS. 8A to 10C of Embodiment 1 described above.

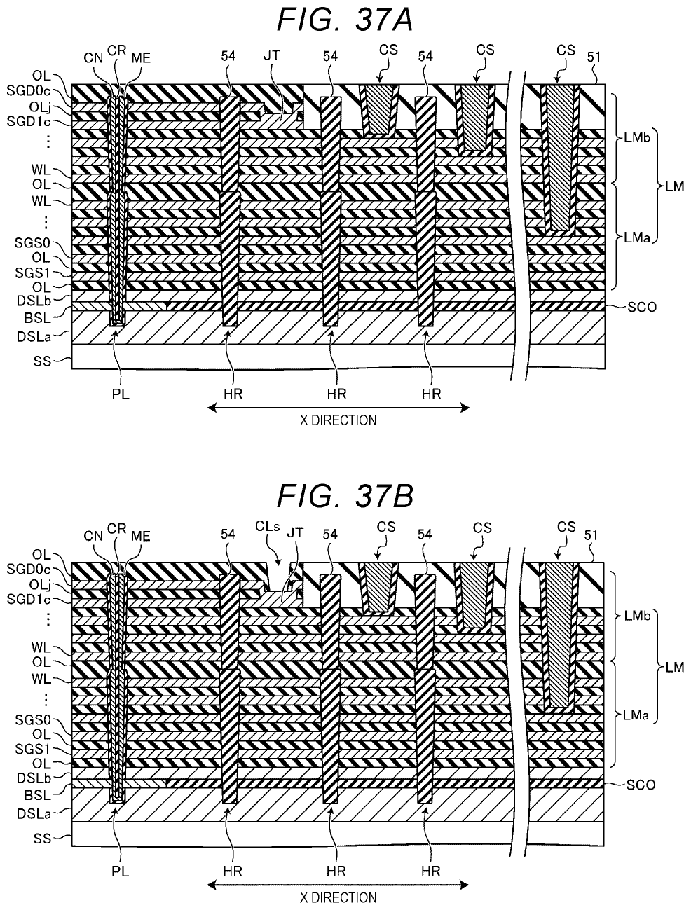

As shown in FIG. 37A, the intermediate sacrificial layer SCN is replaced to form the intermediate source line BSL, and the plurality of insulating layers NL and NLc are replaced to form the plurality of word lines WL and the select gate lines SGD and SGS. By the replacement processing of the insulating layer NLc, a plurality of select gate lines SGD, which are electrically connected to each other at the connection portion JT via the recess RCj of the insulating layer Olj, are formed.

As shown in FIG. 37B, contact holes CLs reaching the select gate line SGD on the upper layer side of the plurality of select gate lines SGD electrically connected to each other are formed.

Subsequent processing is performed in the same manner as in Embodiment 1 and Modification Example 1 of Embodiment 1 described above.

As described above, the semiconductor memory device 2 of Embodiment 2 is manufactured.

### Overview

According to the semiconductor memory device 2 of Embodiment 2, the plurality of select gate lines SGDc are electrically connected to each other via the penetrating portion of the insulating layer Olj interposed between the plurality of select gate lines SGDc. In addition, the contact CCs is connected to the uppermost select gate line SGDc among the plurality of select gate lines SGDc connected to each other. As a result, the contact region Erdc can be further reduced, and the size of the semiconductor memory device 2 can be further reduced.

The semiconductor memory device 2 of Embodiment 2 has the same effects as those of the semiconductor memory device 1 of Embodiment 1 described above.

In Embodiment 2 described above, a configuration in which a plurality of select gate lines SGDc are electrically connected to each other is applied to a configuration corresponding to Modification Example 1 of Embodiment 1. Meanwhile, the configuration of the select gate line SGDc of Embodiment 2 can also be applied to, for example, the configuration of Embodiment 1 or the Modification Example 2 of Embodiment 1.

### Modification Example

In Embodiment 2 described above, the contact CCs connected to the plurality of select gate lines SGDc have a diameter smaller than that of the contact CC connected to the word line WL or the like, for example, as in Embodiment 1 described above. Meanwhile, the contact connected to the plurality of select gate lines SGDc may have a large diameter as in the contact CC connected to the word line WL and the like. Even in this case, by applying the configuration of Embodiment 2 and by connecting the plurality of select gate lines SGDc to each other, the contact region can be sufficiently reduced.

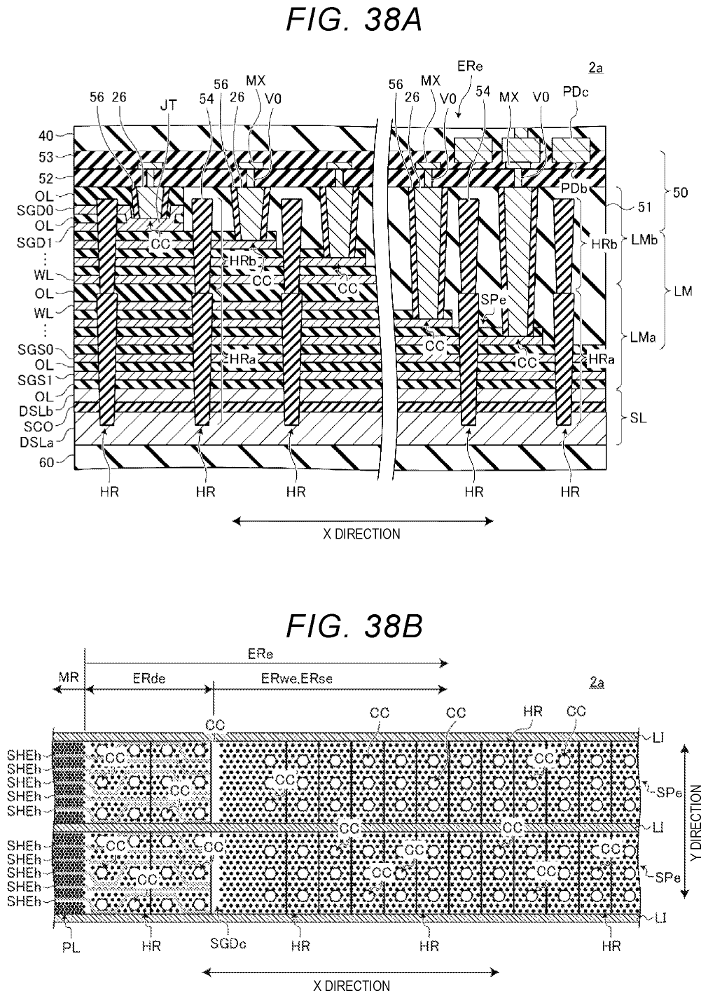

In addition, in the above-described Embodiment 2, the plurality of select gate lines SGDc are processed in a stepped shape. Meanwhile, when not only the select gate line SGDc but also a plurality of word lines WL and the select gate line SGS are processed in a stepped shape, the configuration of Embodiment 2 can be applied. An example of such a configuration is shown in FIGS. 38A and 38B.

FIGS. 38A and 38B are diagrams showing an example of a configuration of the semiconductor memory device 2a according to a modification example of Embodiment 2. More specifically, FIG. 38A is a cross-sectional view taken along the X direction showing an example of the configuration of the contact region Ere. FIG. 38B is an XY cross-sectional view including the contact region Ere at the height position of the select gate line SGDc.

In FIG. 38A, the structure below the insulating layer 60 and the structure above the insulating layer 40 are not shown. In addition, the number, the arrangement, and the like of each configuration in the cross-sectional view in the Y direction of FIG. 38A and those in the XY cross-sectional view of FIG. 38B do not necessarily match.

As shown in FIGS. 38A and 38B, the semiconductor memory device 2a is provided with a stepped part SPe in which the plurality of select gate lines SGD, the word lines WL, and the select gate lines SGS of the stacked body LM are processed in a stepped shape over the entire area. The plurality of select gate lines SGD are electrically connected to each other at the connection portion JT, and one stage of the stepped part SPe is formed by these select gate lines SGD.

A plurality of contacts CC having substantially the same diameter penetrate the insulating layer 51 covering the stepped part SPe to be connected to the terrace surface of each of the word lines WL and the select gate lines SGD and SGS. Among these, in the plurality of select gate lines SGD electrically connected to each other, the contacts CC connected to the select gate line SGD of the uppermost layer are shared with each other.

As described above, the contact region ERe of the semiconductor memory device 2a is provided with the contact region ERde in which the contact CC connected to the select gate line SGD is disposed, and the contact regions ERwe and ERse in which the contact CC connected to the word line WL and the select gate line SGS are respectively disposed, and the stepped part SPe is disposed over the entire contact region ERe.

Even in such a configuration, for example, the area of the contact region ERde can be reduced more effectively than when a plurality of select gate lines SGD are processed in a stepped shape by one layer and the contacts CC are respectively disposed on each of the terrace surfaces.

### Other Embodiments

In the above-described Embodiments 1 and 2 and each of the modification examples thereof, the contact region ER and the like are disposed at both end portions of the stacked body LM in the X direction. However, the arrangement position of the contact region in the stacked body LM is not limited thereto. The contact region may be disposed in the central portion of the stacked body LM, for example, and in this case, the memory region MR can be disposed at both end portions of the stacked body LM, for example.

In addition, in the above-described Embodiments 1 and 2 and each of the modification examples thereof, the pillar PL is connected to the source line SL on the side surface of the channel layer CN, but the present disclosure is not limited thereto. For example, the pillar may be connected to the source line at the lower end portion of the channel layer by removing the memory layer of the lower surface of the pillar.

In addition, in the above-described Embodiments 1 and 2 and each of the modification examples thereof, the columnar portion HR is formed of only the insulating layer 54. However, the columnar portion HR may have the same layer structure as the pillar PL, for example.

In addition, in the above-described Embodiments 1 and 2 and each of the modification examples thereof, the insulating layers NL and OL are stacked in two steps to have the stacked body LM having the 2-tier structure provided with the stacked bodies LMa and LMb. However, the stacked body may have a 1-tier structure or may have a 3-tier or higher structure. By increasing the number of tiers, the number of layers of the word line WL can be further increased.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device, comprising:
a stacked body having a plurality of conductive layers and a plurality of insulating layers alternately stacked on top of each other in a stacking direction;
a pillar extending in the stacked body in the stacking direction of the stacked body and forming a memory cell at intersection portions with at least some of the plurality of conductive layers;
a first separation layer penetrating an uppermost conductive layer of the stacked body and penetrating at least one conductive layer continuous with the uppermost conductive layer in the stacking direction among the plurality of conductive layers, extending in the stacked body in a first direction intersecting the stacking direction, and the first separation layer selectively separating one or more conductive layers including the uppermost conductive layer in a second direction intersecting with the stacking direction and the first direction;
a first contact extending from an upper side of the stacked body and being connected to any one of the one or more conductive layers; and
a second contact extending from the upper side of the stacked body, being connected to any one of the plurality of conductive layers lower than the one or more conductive layers, and the second contact having a diameter on an upper surface that is larger than that of an upper surface of the first contact.

2. The semiconductor memory device according to claim 1,
wherein the second contact is disposed at a position separated from the first contact in the first direction, and
the semiconductor memory device further comprises:
a second separation layer penetrating the one or more conductive layers, extending in the stacked body in the second direction, and selectively separating the one or more conductive layers into a first contact side and a second contact side, at a position between the first contact and the second contact.

3. The semiconductor memory device according to claim 1,
wherein the second contact is disposed at a position separated from the first contact in the first direction,
the stacked body has a first stepped part, in which the uppermost conductive layer and at least one conductive layer continuous with the uppermost conductive layer in the stacking direction among the plurality of conductive layers form a stepped shape, wherein a height position of a terrace surface is lowered from a first contact side toward a second contact side, and
the first separation layer (i) penetrating two or more conductive layers including the uppermost conductive layer, (ii) extending in the stacked body in the first direction, and (iii) selectively separating the two or more conductive layers in the second direction.

4. The semiconductor memory device according to claim 3,
wherein the first contact includes a plurality of first contacts respectively connected to the terrace surfaces of the two or more conductive layers, and
the second contact penetrating a conductive layer lower than the two or more conductive layers and reaching a depth position of a conductive layer to be connected among the plurality of conductive layers.

5. The semiconductor memory device according to claim 3,
wherein the stacked body has a second stepped part in which the two or more conductive layers form a stepped shape, wherein the height position of the terrace surface is lowered from the second contact side toward the first contact side, and which faces the first stepped part in the first direction.

6. The semiconductor memory device according to claim 1,
wherein the first separation layer penetrating the uppermost conductive layer and at least one conductive layer continuous with the uppermost conductive layer in the stacking direction among the plurality of conductive layers, the first separation layer extending in the stacked body in the first direction, and selectively separating two or more conductive layers including the uppermost conductive layer in the second direction, and
the two or more conductive layers are electrically connected to each other via a penetrating portion disposed in an insulating layer interposed between the two or more conductive layers among the plurality of insulating layers.

7. The semiconductor memory device according to claim 6,
wherein the first contact is connected to the uppermost conductive layer among the two or more conductive layers.

8. A semiconductor memory device, comprising:
a stacked body having a plurality of conductive layers and a plurality of insulating layers alternately stacked on top of each other in a stacking direction and having a stepped part in which the plurality of conductive layers form a stepped shape;
a pillar extending in the stacked body in the stacking direction of the stacked body and forming a memory cell at intersection portions with at least some of the plurality of conductive layers;
a separation layer (i) penetrating an uppermost conductive layer of the stacked body and at least one conductive layer continuous with the uppermost conductive layer in the stacking direction among the plurality of conductive layers, (ii) extending in the stacked body in a first direction intersecting the stacking direction, and (iii) selectively separating two or more conductive layers including the uppermost conductive layer in a second direction intersecting with the stacking direction and the first direction;
a first contact extending from an upper side of the stacked body and being connected to the uppermost conductive layer; and
a plurality of second contacts extending from the upper side of the stacked body and being respectively connected to conductive layers lower than the two or more conductive layers among the plurality of conductive layers,
wherein the two or more conductive layers are electrically connected to each other via a penetrating portion disposed in an insulating layer interposed between the two or more conductive layers among the plurality of insulating layers to form one stage of the stepped part.

9. A manufacturing method of a semiconductor memory device, comprising:
forming a first stacked body having a plurality of first insulating layers and a plurality of second insulating layers alternately stacked on top of each other in a stacking direction;
forming a memory hole extending in the first stacked body in the stacking direction of the first stacked body;
forming a first contact hole extending from an upper side of the first stacked body, and reaching an uppermost first insulating layer of the first stacked body and at least one first insulating layer continuous with the uppermost first insulating layer in the stacking direction among the plurality of first insulating layers; and
forming a second contact hole extending from the upper side of the first stacked body, reaching any one of first insulating layers lower than one or more first insulating layers including the uppermost first insulating layer among the plurality of first insulating layers, and the second contact hole having a diameter on an upper end portion that is larger than that of an upper end portion of the first contact hole.

10. The manufacturing method of a semiconductor memory device according to claim 9,
wherein the second contact hole is formed at a position separated from the first contact hole in a first direction intersecting the stacking direction, and
the manufacturing method further comprises:
forming a second stacked body by replacing the plurality of first insulating layers with a plurality of conductive layers;
forming a first separation layer penetrating (i) an uppermost conductive layer of the second stacked body and (ii) at least one conductive layer continuous with the uppermost conductive layer in the stacking direction among the plurality of conductive layers, the first separation layer extending in the second stacked body in the first direction, and selectively separating one or more conductive layers including the uppermost conductive layer in a second direction intersecting with the stacking direction and the first direction; and
forming a second separation layer penetrating the one or more conductive layers, extending in the second stacked body in the second direction, and selectively separating the one or more conductive layers into the first contact hole and the second contact hole, at a position between the first contact hole side and the second contact hole side.

11. The manufacturing method of a semiconductor memory device according to claim 9, further comprising:
forming a penetrating portion penetrating the second insulating layer on the second insulating layer interposed between the uppermost first insulating layer and at least one first insulating layer continuous with the uppermost first insulating layer in the stacking direction among the plurality of first insulating layers, when forming the plurality of second insulating layers; and
connecting two or more first insulating layers including the uppermost first insulating layer to each other via the penetrating portion in the stacking direction, when forming the plurality of first insulating layers.

12. The manufacturing method of a semiconductor memory device according to claim 11, further comprising:
forming a second stacked body in which the plurality of first insulating layers are replaced with a plurality of conductive layers, and wherein the uppermost conductive layer and at least one conductive layer continuous with the uppermost conductive layer in the stacking direction among the plurality of conductive layers are electrically connected to each other.

13. The semiconductor memory device according to claim 1, wherein the plurality of conductive layers are formed of tungsten or molybdenum.

14. The semiconductor memory device according to claim 1, wherein the plurality of insulating layers are formed of silicon oxide.

15. The semiconductor memory device according to claim 1, wherein the pillar includes a memory layer, a channel layer, and a core layer.

16. The semiconductor memory device according to claim 1, wherein the first separation layer is formed of silicon oxide.

17. The semiconductor memory device according to claim 1, wherein the first contact is formed of a conducting material.
